(19) United States
(12) Patent Application Publication
(10) Pub. No.: US 2013/0341077 A1
(43) Pub. Date: Dec. 26, 2013

(54) METHOD FOR REPAIRING DISCONNECTION IN WIRING BOARD, METHOD FOR MANUFACTURING WIRING BOARD, METHOD FOR FORMING WIRING IN WIRING BOARD AND WIRING BOARD

(71) Applicant: IBIDEN CO., LTD., Ogaki-shi (JP)

(72) Inventors: Shinji OUCHI, Ogaki-shi (JP); Hirokazu HIGASHI, Ogaki-shi (JP)

(73) Assignee: IBIDEN CO., LTD., Ogaki-shi (JP)

(21) Appl. No.: 13/752,768

(22) Filed: Jan. 29, 2013

Related U.S. Application Data
(60) Provisional application No. 61/663,772, filed on Jun. 25, 2012.

(51) Int. Cl. H05K 3/22; H05K 1/11

(52) U.S. Cl. CPC H05K 3/225; H05K 1/115
USPC 174/264; 264/36.18

(57) ABSTRACT

A method for repairing a disconnection in a wiring board includes positioning a substrate including an insulation layer and a conductive layer formed on the insulation layer, the conductive layer having a wiring line disconnected such that the wiring line has a disconnected portion formed between conductive patterns forming the wiring line, applying in the disconnected portion between the conductive patterns a conductive paste including a non-conductive material and conductive particles such that the conductive paste fills the disconnected portion between the conductive patterns and joins the conductive patterns forming the wiring line in the conductive layer, and irradiating laser upon the conductive paste applied in the disconnected portion such that at least a portion of the conductive paste in the disconnected portion is sintered and forms a sintered portion connecting the conductive patterns of the wiring line in the conductive layer.

### CROSS-REFERENCE TO RELATED APPLICATIONS

The present application is based upon and claims the benefit of priority from U.S. Application No. 61/663,772, filed Jun. 25, 2012, the entire contents of which are incorporated herein by reference.

### BACKGROUND OF THE INVENTION

1. Field of the Invention

The present invention relates to a method for repairing a disconnection in a wiring board, a method for manufacturing a wiring board, a method for forming wiring in a wiring board, and a wiring board.

2. Description of Background Art

Japanese Laid-Open Patent Publication 2000-151081 describes a method for repairing a disconnection in a wiring board, in which resist is formed in portions except for a circuit pattern that includes a disconnected portion, conductive paste is applied to the disconnected portion from above the resist, a resin in the conductive paste is cured, and the resist is removed from the wiring board. The contents of Japanese Laid-Open Patent Publication 2000-151081 are incorporated herein in this application.

### SUMMARY OF THE INVENTION

According to one aspect of the present invention, a method for repairing a disconnection in a wiring board includes positioning a substrate including an insulation layer and a conductive layer formed on the insulation layer, the conductive layer having a wiring line disconnected such that the wiring line has a disconnected portion formed between conductive patterns forming the wiring line, applying in the disconnected portion between the conductive patterns a conductive paste including a non-conductive material and conductive particles such that the conductive paste fills the disconnected portion between the conductive patterns and joins the conductive patterns forming the wiring line in the conductive layer, and irradiating laser upon the conductive paste applied in the disconnected portion such that at least a portion of the conductive paste in the disconnected portion is sintered and forms a sintered portion connecting the conductive patterns of the wiring line in the conductive layer.

According to another aspect of the present invention, a method for forming wiring in a wiring board includes preparing a substrate including an insulation layer and a conductive layer formed on the insulation layer, the conductive layer including conductive patterns forming a space between the conductive patterns, applying in the space between the conductive patterns a conductive paste including a non-conductive material and conductive particles such that the conductive paste fills the space between the conductive patterns and joins the conductive patterns in the conductive layer, and irradiating laser upon the conductive paste applied in the space such that at least a portion of the conductive paste in the space is sintered and forms a sintered portion connecting the conductive patterns forming a wiring line in the conductive layer.

According to yet another aspect of the present invention, a wiring board includes an insulation layer, a conductive layer formed on the insulation layer and including a first conductive pattern and a second conductive pattern, and a sintered structure formed on the insulation layer and extending in a space between the first conductive pattern and the second conductive pattern such that the sintered structure is connecting the first conductive pattern and the second conductive pattern. The sintered structure has an electric resistance which is in a range of 1.2˜5.0 times an electric resistance of the first conductive pattern and an electric resistance of the second conductive pattern.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a flowchart showing a method for repairing a disconnection in a wiring board according to a first embodiment of the present invention;

FIG. 2A, in the method for repairing a disconnection in a wiring board shown in FIG. 1, is a plan view illustrating a step for preparing a substrate;

FIG. 2B is a cross-sectional view of FIG. 2A;

FIG. 3 is a cross-sectional view illustrating a first example of the substrate prepared in a step shown in FIG. 2A;

FIG. 4 is a cross-sectional view illustrating a second example of the substrate prepared in a step shown in FIG. 2A;

FIG. 5 is a cross-sectional view illustrating a third example of the substrate prepared in a step shown in FIG. 2A;

FIG. 6 is a cross-sectional view illustrating a fourth example of the substrate prepared in a step shown in FIG. 2A;

FIG. 7 is a cross-sectional view illustrating a fifth example of the substrate prepared in a step shown in FIG. 2A;

FIG. 8 is a cross-sectional view illustrating a sixth example of the substrate prepared in a step shown in FIG. 2A;

FIG. 9 is a cross-sectional view illustrating a seventh example of the substrate prepared in a step shown in FIG. 2A;

FIG. 10 is a cross-sectional view illustrating an eighth example of the substrate prepared in a step shown in FIG. 2A;

FIG. 11A, in the method for repairing a disconnection in a wiring board shown in FIG. 1, is a plan view illustrating a step for forming (applying) conductive paste in a portion where wiring is disconnected;

FIG. 11B is a cross-sectional view of FIG. 11A;

FIG. 12A, in the method for repairing a disconnection in a wiring board shown in FIG. 1, is a plan view illustrating a step for sintering the conductive paste;

FIG. 12B is a cross-sectional view of FIG. 12A;

FIG. 13A is a plan view showing the unsintered conductive paste and the sintered conductive paste after the step in FIG. 12A;

FIG. 13B is a cross-sectional view of FIG. 13A;

FIG. 14, in the method for repairing a disconnection in a wiring board shown in FIG. 1, is a plan view illustrating a step for removing the unsintered conductive paste;

FIG. 15 is a plan view showing a state after the step in FIG. 14;

FIG. 16A, in the method for repairing a disconnection in a wiring board shown in FIG. 1, is a perspective view showing a first stage;

FIG. 16B, in the method for repairing a disconnection in a wiring board shown in FIG. 1, is a perspective view showing a second stage;

FIG. 16C, in the method for repairing a disconnection in a wiring board shown in FIG. 1, is a perspective view showing a third stage;

FIG. 17 is a view illustrating an example of repairing a disconnection among multiple wiring lines positioned parallel;

FIG. 18 is a view illustrating an example of repairing multiple disconnections positioned parallel;

FIG. 19 is a graph showing the relationship between electric current and voltage in an undisconnected portion (copper wiring) and a repaired portion (conductive paste) respectively of a wiring line formed by the method for forming wiring in a wiring board according to the first embodiment of the present invention;

FIG. 20 is a table showing Samples A˜C in Test 1 and the test results (evaluations) of each sample;

FIG. 21A is a view illustrating a method for sintering Sample A;

FIG. 21B is a view illustrating a method for sintering Sample B;

FIG. 21C is a view illustrating a method for sintering Sample C;

FIG. 22A is an SEM photograph showing the sintered state of Sample A;

FIG. 22B is an SEM photograph showing the sintered state of Sample B;

FIG. 22C is an SEM photograph showing the sintered state of Sample C;

FIG. 23 is a table showing Samples D˜I in Test 2 and the test results (evaluations) of each sample;

FIG. 24A is an SEM photograph showing the sintered state of Sample D;

FIG. 24B is an SEM photograph showing the sintered state of Sample E;

FIG. 25A is an SEM photograph showing the sintered state of Sample F;

FIG. 25B is an SEM photograph showing the sintered state of Sample G;

FIG. 26A is an SEM photograph showing the sintered state of Sample H;

FIG. 26B is an SEM photograph showing the sintered state of Sample I;

FIG. 27 is a view illustrating Test 3;

FIG. 28 is an SEM photograph showing the sintered state of Sample J in Test 3;

FIG. 29 is an SEM photograph showing the sintered state of Sample K in Test 3;

FIG. 30 is a table showing Samples L˜O in Test 4 and the test results (evaluations) of each sample;

FIG. 31A is an SEM photograph showing the sintered state of Sample L;

FIG. 31B is an SEM photograph showing the sintered state of Sample M;

FIG. 32A is an SEM photograph showing the sintered state of Sample N;

FIG. 32B is an SEM photograph showing the sintered state of Sample O;

FIG. 33 is a graph showing the relationship between wavelength and reflectance of Ag (silver) and Cu (copper) respectively;

FIG. 34 is a flowchart showing a method for repairing a disconnection in a wiring board according to a second embodiment of the present invention;

FIG. 35A, in the method for repairing a disconnection in a wiring board shown in FIG. 34, is a plan view illustrating a step for positioning a mask to surround a space between a first conductive pattern and a second conductive pattern;

FIG. 35B is a cross-sectional view of FIG. 35A;

FIG. 36A, in the method for repairing a disconnection in a wiring board shown in FIG. 34, is a plan view illustrating a step for forming (applying) conductive paste in a portion where wiring is disconnected;

FIG. 36B is a cross-sectional view of FIG. 36A;

FIG. 37A, in the method for repairing a disconnection in a wiring board shown in FIG. 34, is a plan view illustrating a step for removing the mask;

FIG. 37B is a cross-sectional view of FIG. 37A;

FIG. 38, in the method for repairing a disconnection in a wiring board shown in FIG. 34, is a plan view illustrating a step for sintering the conductive paste;

FIG. 39 is a cross-sectional view showing a state after the step in FIG. 38;

FIG. 40 is a flowchart showing a method for repairing a disconnection in a wiring board according to a third embodiment of the present invention;

FIG. 41, in the method for repairing a disconnection in a wiring board shown in FIG. 40, is a cross-sectional view illustrating a step for forming a recess on a surface of the insulation layer positioned in a space between a first conductive pattern and a second conductive pattern;

FIG. 42 is a cross-sectional view showing the wiring formed in a space with a recess formed by the step in FIG. 41;

FIG. 43, in another embodiment of the present invention, is a cross-sectional view illustrating a step for positioning a mask to surround a space between a first conductive pattern and a second conductive pattern, and for forming a recess on a surface of the insulation layer positioned in the space;

FIG. 44 is a cross-sectional view showing the wiring formed in a space with a recess formed by the step in FIG. 43;

FIG. 45 is a flowchart showing a method for manufacturing a wiring board according to a fourth embodiment of the present invention;

FIG. 46, in the method for repairing a disconnection in a wiring board shown in FIG. 45, is a cross-sectional view illustrating a step for forming wiring in a space between a first conductive pattern and a second conductive pattern;

FIG. 47, in the method for repairing a disconnection in a wiring board shown in FIG. 45, is a cross-sectional view illustrating a step for forming another insulation layer on the conductive layer, and for forming another conductive layer on that insulation layer;

FIG. 48A, in yet another embodiment of the present invention, is a plan view showing an example where the width of wiring (conductive paste) formed in a space between a first conductive pattern and a second conductive pattern is set greater than the width of the first conductive pattern or the second conductive pattern;

FIG. 48B, in yet another embodiment of the present invention, is a plan view showing an example where the width of wiring (conductive paste) formed in a space between a first conductive pattern and a second conductive pattern is set smaller than the width of the first conductive pattern or the second conductive pattern;

FIG. 48C, in yet another embodiment of the present invention, is a plan view showing an example where the width of end portions of wiring (conductive paste) formed in a space between a first conductive pattern and a second conductive pattern is set greater than the width of the central portion of the wiring (conductive paste);

FIG. 49A, in yet another embodiment of the present invention, is a cross-sectional view showing an example where the thickness of wiring (conductive paste) formed in a space between a first conductive pattern and a second conductive pattern is set greater than the thickness of the first conductive pattern or the second conductive pattern;

FIG. 49B, in yet another embodiment of the present invention, is a cross-sectional view showing an example where the thickness of wiring (conductive paste) formed in a space between a first conductive pattern and a second conductive pattern is set smaller than the thickness of the first conductive pattern or the second conductive pattern;

FIG. 50A, in yet another embodiment of the present invention, is a cross-sectional view showing an example where the opening portion of a mask positioned surrounding a space between a first conductive pattern and a second conductive pattern has substantially the same opening area as the space;

FIG. 50B, in yet another embodiment of the present invention, is a cross-sectional view showing an example where the opening portion of a mask positioned surrounding a space between a first conductive pattern and a second conductive pattern has a smaller opening area than the space;

FIG. 51A, in yet another embodiment of the present invention, is a plan view showing an example where, prior to forming conductive paste, two linear masks are positioned on the insulation layer in such a way that they face each other by sandwiching a space between a first conductive pattern and a second conductive pattern;

FIG. 51B, in yet another embodiment of the present invention, is a plan view showing an example where, prior to forming conductive paste, two arc-shaped masks are positioned on the insulation layer in such a way that they face each other by sandwiching a space between a first conductive pattern and a second conductive pattern;

FIG. 52A, in yet another embodiment of the present invention, is a cross-sectional view showing an example where, prior to forming conductive paste, a recess is formed on a surface of the insulation layer positioned in a space between a first conductive pattern and a second conductive pattern in such a way to have a smaller opening area than the space;

FIG. 52B, in yet another embodiment of the present invention, is a cross-sectional view showing an example where, prior to forming conductive paste, a recess whose opening area varies depending on its depth is formed on a surface of the insulation layer positioned in a space between a first conductive pattern and a second conductive pattern; and

FIG. 52C, in yet another embodiment of the present invention, is a cross-sectional view showing an example where, prior to forming conductive paste, a recess is formed in a way to expose lower surfaces of a first conductive pattern and a second conductive pattern.

### DETAILED DESCRIPTION OF THE EMBODIMENTS

The embodiments will now be described with reference to the accompanying drawings, wherein like reference numerals designate corresponding or identical elements throughout the various drawings.

In the drawings, arrows (Z1, Z2) each indicate a lamination direction in a wiring board (or a thickness direction of the wiring board) corresponding to a direction along a normal line to the main surfaces (upper and lower surfaces) of the wiring board. On the other hand, arrows (X1, X2) and (Y1, Y2) each indicate a direction perpendicular to a lamination direction (directions to a side of each layer). The main surfaces of the wiring board are on the X-Y plane. Side surfaces of the wiring board are on the X-Z plane or the Y-Z plane. In a lamination direction, a side closer to the core of the wiring board is referred to as a lower layer, and the side farther from the core as an upper layer.

Conductive layers are formed with one or multiple conductive patterns. Conductive layers may include a conductive pattern to form an electrical circuit, such as wiring (including ground), a pad or a land; or conductive layers may include a planar conductive pattern that does not form an electrical circuit.

Opening portions include a notch, a cut or the like in addition to a hole and a groove. Holes are not limited to penetrating holes, but include non-penetrating holes.

Plating includes wet plating such as electrolytic plating and electroless plating as well as dry plating such as PVD (physical vapor deposition) and CVD (chemical vapor deposition).

Light is not limited to visible light. In addition to visible light, light includes electromagnetic waves with short wavelengths such as UV rays and X rays as well as electromagnetic waves with long wavelengths such as infrared rays.

### First Embodiment

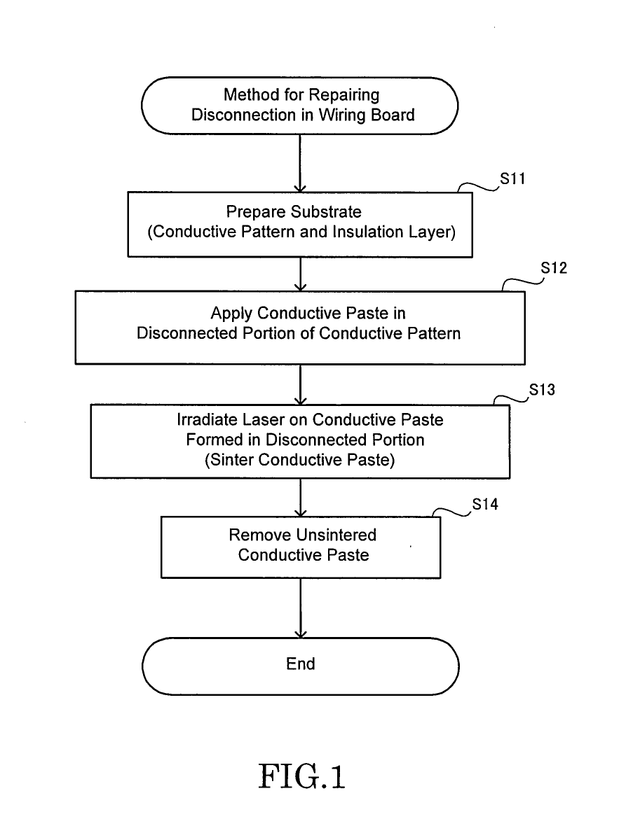

FIG. 1 schematically shows a method for forming wiring in a wiring board (a method for repairing a disconnection) according to the present embodiment. In the present embodiment, a disconnection is repaired by forming wiring.

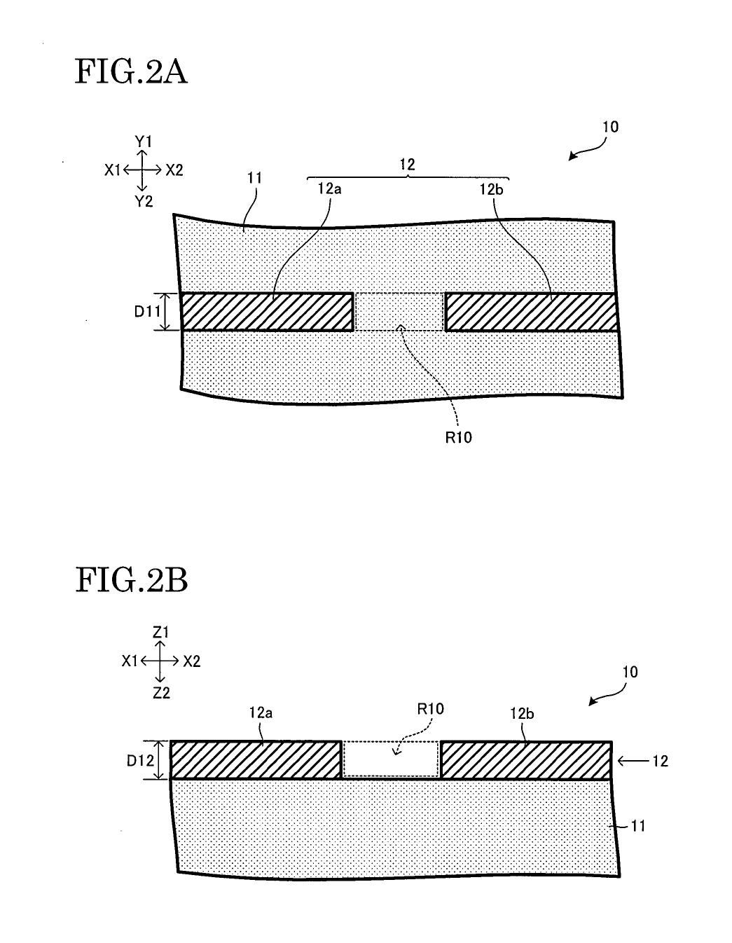

In step (S11) of FIG. 1, substrate 10 having insulation layer 11 and conductive layer 12 is prepared as shown in FIG. 2A and FIG. 2B (a cross-sectional view of FIG. 2A). Conductive layer 12 is formed on insulation layer 11, and includes conductive pattern (12a) (first conductive pattern) and conductive pattern (12b) (second conductive pattern). Space (R10) is present between conductive pattern (12a) and conductive pattern (12b). In the present embodiment, conductive pattern (12a) and conductive pattern (12b) are formed when one wiring line is disconnected. In the present embodiment, space (R10) corresponds to a disconnected portion of the wiring. Since conductive patterns (12a, 12b) originally formed one wiring line, they are made of the same material as each other. In addition, conductive patterns (12a, 12b) have substantially the same width (width (D11), for example) and substantially the same thickness (thickness (D12), for example) as each other.

In FIG. 2A, width (D11) of conductive pattern (12a) or (12b) (the average value if not uniform) is 50 μm, for example. Also, in FIG. 2B, thickness (D12) of conductive pattern (12a) or (12b) (the maximum value if not uniform) is 12 μm, for example.

In the present embodiment, the glass transition temperature (Tg) of insulation layer 11 is 160° C., for example.

Insulation layer 11 is made of resin containing core material, for example. Specifically, insulation layer 11 is made by impregnating glass cloth (core material) with epoxy resin (hereinafter referred to as glass epoxy), for example. In a preferred example, core material is dispersed substantially uniformly in substantially the entire insulation layer 11. However, that is not the only option, and core material may be dispersed only in the surface layer portions of insulation layer 11. The core material has a lower thermal expansion coefficient than the main material (epoxy resin in the present embodiment).

The material of insulation layer 11 is not limited to the above and may be of any other material. For example, the resin of insulation layer 11 may be thermosetting resins such as phenol resin, polyphenylene ether (PPE), polyphenylene oxide (PPO), fluororesin, LCP (liquid crystal polymer), polyester resin, imide resin (polyimide), BT resin, allyl polyphenylene ether resin (A-PPE resin) and aramid resin. It is easy to cure thermosetting resins by heating. As for core materials, glass fiber (such as glass cloth and nonwoven glass fabric), aramid fiber (such as nonwoven aramid fabric), or inorganic material such as silica filler is thought to be preferable. Furthermore, insulation layer 11 may contain inorganic filler (such as silica filler) in addition to core material. Inorganic filler may be dispersed substantially uniformly in substantially the entire insulation layer 11, for example, or may be dispersed only in the surface layer portions of insulation layer 11. Also, insulation layer 11 may be made of resin that contains neither core material nor inorganic filler. Insulation layer 11 may be formed with multiple layers of different insulative materials.

Conductive layer 12 is formed with copper foil (lower layer) and copper plating (upper layer), for example, or it is formed with either one of such materials.

The method for forming conductive layer 12 is not limited specifically. For example, a copper-clad laminate is prepared as insulation layer 11, and the copper foil on insulation layer 11 may be used to form conductive layer 12 by a subtractive method. Alternatively, conductive layer 12 may be formed by any one of the following methods or any combination of two or more of those: panel plating, pattern plating, full-additive, semi-additive (SAP), subtractive, transfer and tenting methods.

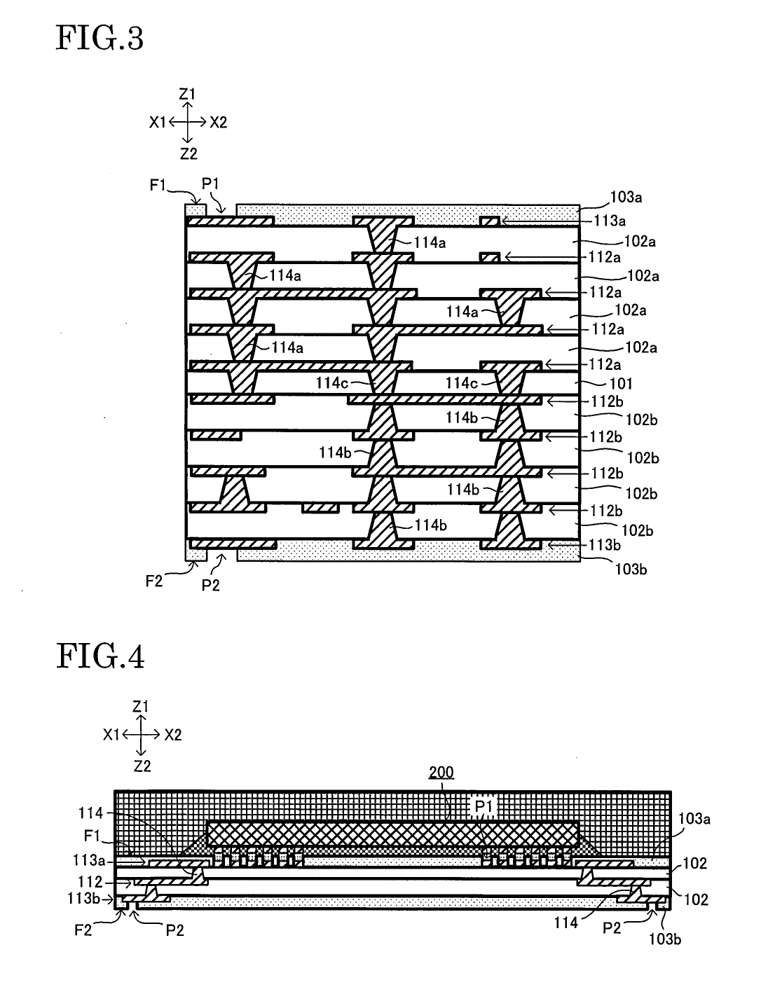

Substrate 10 forms part of a wiring board shown in any of FIGS. 3-10, for example.

The wiring board shown in FIG. 3 is a buildup multilayer printed wiring board. Specifically, as shown in FIG. 3, the wiring board has core substrate 101, conductive layers (112a) and insulation layers (102a) (interlayer insulation layers) alternately laminated on one side of core substrate 101, and conductive layers (112b) and insulation layers (102b) (interlayer insulation layers) alternately laminated on the other side of core substrate 101. Also, outermost conductive layer (113a) is formed on insulation layer (102a) positioned outermost on one side, and outermost conductive layer (113b) is formed on insulation layer (102b) positioned outermost on the other side.

Conductive layer (112a) on core substrate 101 and conductive layer (112b) on core substrate 101 are connected to each other by via conductor (114c) formed in core substrate 101. Conductive layers (112a), or conductive layer (112a) and outermost conductive layer (113a), are connected to each other by via conductor (114a) formed in insulation layer (102a). Conductive layers (112b), or conductive layer (112b) and outermost conductive layer (113b), are connected to each other by via conductor (114b) formed in insulation layer (102b).

Solder resist (103a) is formed on outermost insulation layer (102a) and outermost conductive layer (113a), and solder resist (103b) is formed on outermost insulation layer (102b) and outermost conductive layer (113b). Opening portions are formed respectively in solder resists (103a, 103b), and outermost conductive layers (113a, 113b) exposed in their respective opening portions become pads (P1, P2) (external connection terminals). Pads (P1) are formed on surface (F1) (the Z1-side main surface) of the wiring board, and pads (P2) are formed on surface (F2) (the Z2-side main surface) of the wiring board. Another wiring board or an electronic component or the like may be mounted on pads (P1, P2).

Substrate 10 prepared in step (S11) of FIG. 1 may be part of the wiring board shown in FIG. 3, for example. Specifically, it is an option for insulation layer 11 to correspond to insulation layer (102a), and for conductive layer 12 to correspond to outermost conductive layer (113a). It is also an option for insulation layer 11 to correspond to core substrate 101 or insulation layer (102a), and for conductive layer 12 to correspond to conductive layer (112a) on core substrate 101 or on insulation layer (102a). Alternatively, substrate 10 may be another part of the wiring board shown in FIG. 3.

The wiring board shown in FIG. 4 is a coreless wiring board that does not include a core substrate. Specifically, as shown in FIG. 4, the wiring board is formed by alternately laminating conductive layers (outermost conductive layer (113b), conductive layer 112, outermost conductive layer (113a)) and interlayer insulation layers (insulation layers (102, 102)). Conductive layers are connected to each other by via conductor 114 formed in insulation layer 102.

Electronic component 200 is mounted on a surface of the wiring board (outermost conductive layer (113a), for example). In the example shown in FIG. 4, terminal pitches in the wiring board are set to fan out from pads (P1) on the electronic component 200 side toward pads (P2) on the other side.

Substrate 10 prepared in step (S11) of FIG. 1 may be part of the wiring board shown in FIG. 4, for example. Specifically, it is an option for insulation layer 11 to correspond to outermost (electronic component 200 side) insulation layer 102, and for conductive layer 12 to correspond to outermost conductive layer (113a) on insulation layer 102. Alternatively, substrate 10 may be another part of the wiring board shown in FIG. 4.

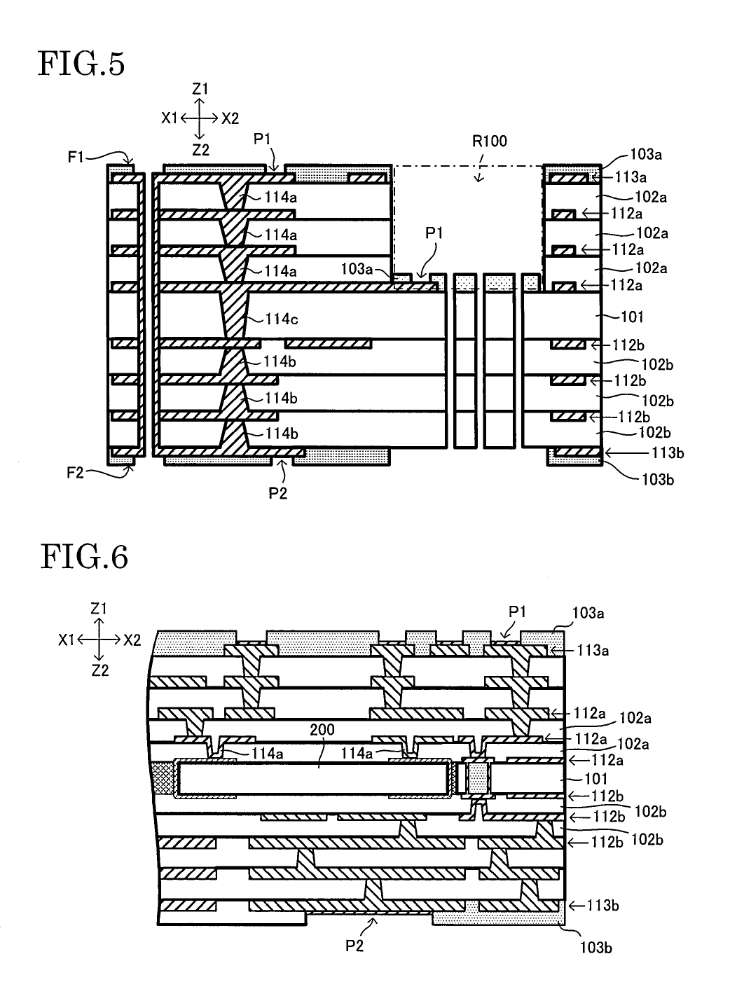

The wiring board shown in FIG. 5 has an accommodation section for accommodating an electronic component or another wiring board. Specifically, opening section (R100) (accommodation section) which opens on surface (F1) is formed in the wiring board as shown in FIG. 5.

Substrate 10 prepared in step (S11) of FIG. 1 may be part of the wiring board shown in FIG. 5, for example. Specifically, it is an option for insulation layer 11 to correspond to core substrate 101, and for conductive layer 12 to correspond to conductive layer (112a) on core substrate 101 exposed on the bottom surface of opening section (R100). Alternatively, substrate 10 may be another part of the wiring board shown in FIG. 5.

The wiring board shown in FIG. 6 has a built-in electronic component. Specifically, an opening section (such as a hole penetrating through core substrate 101) is formed in core substrate 101 of the wiring board, and electronic component 200 (a capacitor, for example) is positioned in the opening section, as shown in FIG. 6.

Substrate 10 prepared in step (S11) of FIG. 1 may be part of the wiring board shown in FIG. 6, for example. Specifically, it is an option for insulation layer 11 to correspond to core substrate 101, and for conductive layer 12 to correspond to conductive layer (112a) on core substrate 101. It is also an option for insulation layer 11 to correspond to insulation layer (102a) on electronic component 200, and for conductive layer 12 to correspond to conductive layer (112a) connected to an electrode of electronic component 200 by via conductor (114a) formed in that insulation layer (102a). Alternatively, substrate 10 may be another part of the wiring board shown in FIG. 6.

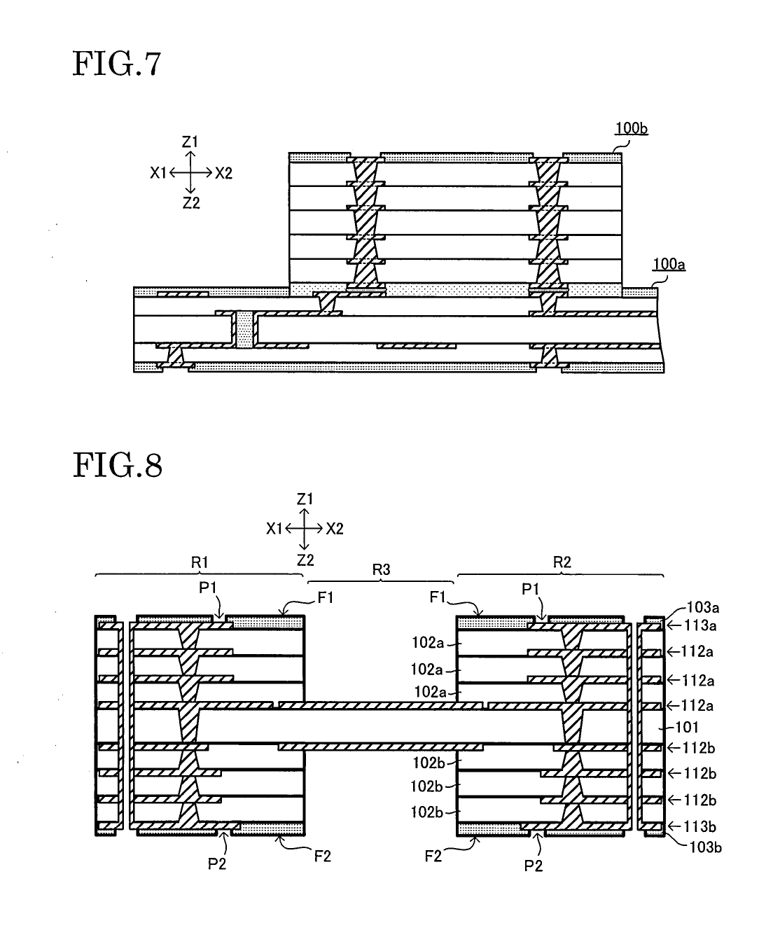

The wiring board shown in FIG. 7 is made up of multiple wiring boards. Especially, the wiring board is formed by mounting wiring board (100b) (a buildup multilayer printed wiring board, for example) on wiring board (100a) (a motherboard, for example) as shown in FIG. 7.

Substrate 10 prepared in step (S11) of FIG. 1 may be part of either wiring board (100a) or (100b) shown in FIG. 7, for example.

Wiring boards shown in FIGS. 8˜10 are each a flex-rigid wiring board having rigid sections (R1, R2) and flexible section (R3).

The wiring board shown in FIG. 8 has core substrate 101 made of flexible material. Core substrate 101 is formed through the entire wiring board. An end portion of core substrate 101 becomes rigid section (R1) or (R2) by laminating a certain number of rigid layers (insulation layers (102a, 102b), conductive layers (112a, 112b) and outermost conductive layers (113a, 113b)) on both of its sides. The central portion of core substrate 101 becomes flexible section (R3) where most of the rigid layers are not laminated on both of its sides.

Substrate 10 prepared in step (S11) of FIG. 1 may be part of the wiring board shown in FIG. 8, for example. Specifically, it is an option for insulation layer 11 to correspond to core substrate 101, and for conductive layer 12 to correspond to conductive layer (112a) on core substrate 101 in flexible section (R3). Alternatively, insulation layer 11 and conductive layer 12 may each be part of rigid section (R1) or (R2). Yet alternatively, substrate 10 may be another part of the wiring board shown in FIG. 8.

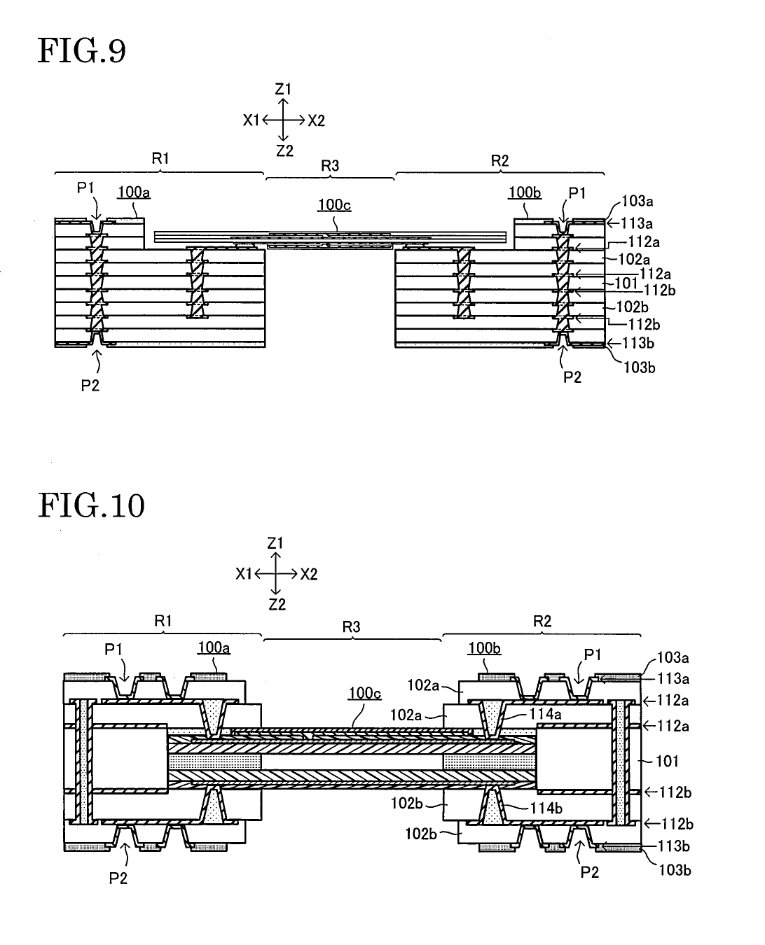

The wiring board shown in FIG. 9 is formed with wiring boards (100a, 100b) (each a rigid wiring board) and wiring board (100c) (flexible wiring board). Either end portion of wiring board (100c) is connected to a surface of wiring board (100a) or (100b) through soldering or the like. Wiring board (100a) and wiring board (100b) are connected to each other by wiring board (100c). Either end portion of wiring board (100c) forms rigid section (R1) or (R2), and the central portion of wiring board (100c) forms flexible section (R3).

Substrate 10 prepared in step (S11) of FIG. 1 may be part of the wiring board shown in FIG. 9, for example. Specifically, insulation layer 11 and conductive layer 12 may each be part of wiring board (100a) or (100b). Alternatively, insulation layer 11 and conductive layer 12 may each be part of wiring board (100c). Yet alternatively, substrate 10 may be another part of the wiring board shown in FIG. 9.

The wiring board shown in FIG. 10 is formed with wiring boards (100a, 100b) (each a rigid wiring board) and wiring board (100c) (flexible wiring board). Wiring board (100c) is positioned to a side of core substrates 101 of wiring boards (100a, 100b). Both end portions of wiring board (100c) are sandwiched by insulation layers (102a, 102b). Conductive layer (112a) on insulation layer (102a) is connected to a conductive layer of wiring board (100c) by via conductor (114a) formed in insulation layer (102a), and conductive layer (112b) on insulation layer (102b) is connected to a conductive layer of wiring board (100c) by via conductor (114b) formed in insulation layer (102b). Wiring board (100a) and wiring board (100b) are connected to each other by wiring board (100c). Either end portion of wiring board (100c) forms rigid section (R1) or (R2), and the central portion of wiring board (100c) forms flexible section (R3).

Substrate 10 prepared in step (S11) of FIG. 1 may be part of the wiring board shown in FIG. 10, for example. Specifically, it is an option for insulation layer 11 to correspond to insulation layer (102a) formed on wiring board (100c), and for conductive layer 12 to correspond to conductive layer (112a) connected to a conductive layer of wiring board (100c) by via conductor (114a) formed in that insulation layer (102a). Alternatively, insulation layer 11 and conductive layer 12 may each be part of wiring board (100c). Yet alternatively, substrate 10 may be another part of the wiring board shown in FIG. 10.

Wiring boards shown in FIGS. 3˜7 may each be a rigid wiring board or a flexible wiring board. Alternatively, each wiring board may be a double-sided wiring board or a single-sided wiring board. Moreover, the measurements and the number of layers of conductive layers and insulation layers in each wiring board may be determined freely.

Substrate 10 prepared in step (S11) of FIG. 1 is not limited to being part of a wiring board shown in FIGS. 3˜10, and may be selected freely.

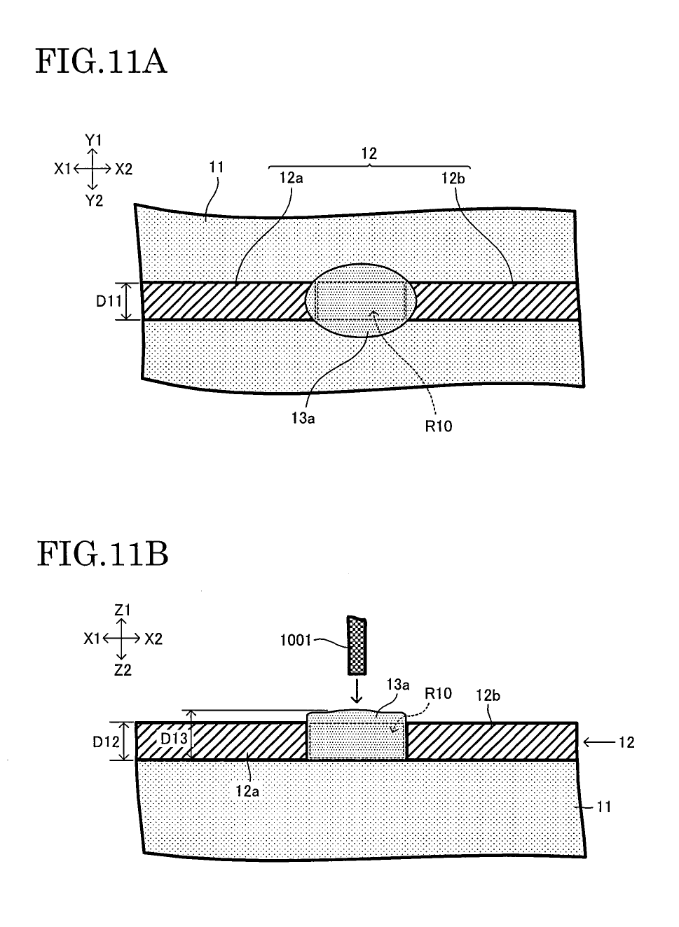

In step (S12) of FIG. 1, conductive paste (13a) is formed (applied, for example) in space (R10) between conductive patterns (12a) and (12b) by inkjet, for example, as shown in FIG. 11A and FIG. 11B (cross-sectional view of FIG. 11A). Specifically, liquid conductive paste (13a) is discharged from nozzle 1001 of the inkjet. The viscosity of conductive paste (13a) is 10000 cp, for example, and the particle diameter of conductive paste (13a) (diameter of a particle) is 100 nm, for example. In the present embodiment, conductive paste (13a) is applied in such a way that the thickness of conductive paste (13a) before curing (the average value if not uniform) is greater than any thickness of conductive patterns (12a, 12b).

Conductive paste (13a) is made of conductive particles and a binder (solvent). Conductive paste (13a) is a silver paste in the present embodiment.

At this stage, conductive paste (13a) is formed on insulation layer 11 and on conductive patterns (12a,12b) near space (R10) as shown in FIG. 11A. Conductive paste (13a) has a greater area than space (R10) on the X-Y plane, covering the entire space (R10). Also, thickness (D13) of conductive paste (13a) (the average value if not uniform) in FIG. 11B is 20 μm, for example.

In the present embodiment, conductive particles in conductive paste (13a) are made of silver. Silver has high conductivity. It is thought that the amount of conductive particles contained in conductive paste (13a) is preferred to be in a range of 50 wt. % or greater, more preferably in a range of 70 wt. % or greater. However, that is not the only option, and conductive particles in conductive paste (13a) may be made of copper. When copper is used both for conductive particles in conductive paste (13a) and for conductive patterns (12a,12b), conductive particles in conductive paste (13a) and conductive patterns (12a,12b) are formed by the same material, making it easier to set the same characteristics as each other (chemical and physical properties, for example). As a result, it is easier to set the entire wiring portions of conductive paste (13a) and conductive patterns (12a,12b) to have uniform characteristics. Alternatively, conductive particles in conductive paste (13a) may be made of gold. Gold has excellent conductivity and chemical stability.

If required, conductive paste (13a) is dried after conductive paste (13a) is formed (in step (S12)) but before laser light is irradiated (in step (S13)). The sintered state of conductive paste (13a) varies depending on whether the paste is dried or not. The reason is provided later.

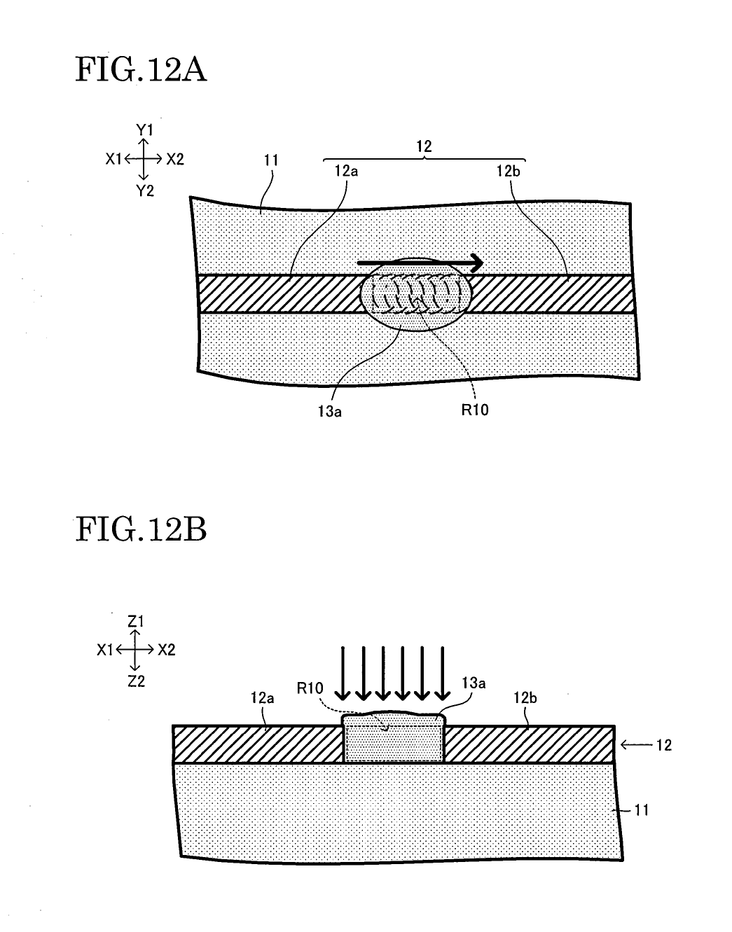

In step (S13) of FIG. 1, conductive paste (13a) formed in space (R10) (disconnected portion) is sintered by irradiating laser light as shown in FIG. 12A and FIG. 12B (cross-sectional view of FIG. 12A). Laser light is irradiated at room temperature and under atmospheric pressure, for example, allowing insulation layer 11 with a low glass transition temperature (Tg) to be used. In the present embodiment, conductive paste (13a) is sintered by irradiating laser light multiple times.

In the present embodiment, laser light is irradiated selectively on conductive paste (13a) positioned in space (R10). Therefore, it is not required to form resist in portions except for the disconnected portion. As a result, repairing a disconnection is simplified.

In the present embodiment, laser light is irradiated only on the targeted portion (conductive paste (13a) positioned in space (R10)) without using a shading mask (maskless, for example) by halting laser irradiation on untargeted portions. However, that is not the only option, and laser light may be irradiated on the entire surface of the irradiation target by placing a shading mask with an opening portion corresponding to the position that requires irradiation.

In the present embodiment, positions to irradiate laser light are moved in direction X, for example, as shown in FIG. 12A. Positions to irradiate laser light may be changed by a galvanometer mirror, for example, or the irradiation target may be moved using a conveyor. Alternatively, the light emitted by a laser may be set to be linear light using a cylindrical lens, for example. Yet alternatively, without setting the laser focus completely at the irradiation portion, the irradiation target may be processed using the light which is shifted to direction Z (defocused light). If defocused light is used, while the spot diameter increases, laser intensity decreases, allowing soft processing.

Laser intensity (amount of light) is preferred to be adjusted by pulse control. In particular, for example, when laser intensity is required to be changed, the number of shots (number of irradiations) is changed without changing the laser intensity per shot (one irradiation). Namely, when required laser intensity is not obtained by one shot, laser light is irradiated again at the same irradiation spot. Since time for changing irradiation conditions is omitted by using such an adjustment method, throughput is thought to be improved. However, that is not the only option, and the method for adjusting laser intensity may be selected freely. For example, irradiation conditions may be determined for each irradiation spot, while the number of irradiations is set constant (for example, one shot per irradiation spot).

It is preferred to set the waveform and wavelength of laser light and output of laser irradiation according to usage requirements or the like. The sintered state of conductive paste (13a) varies depending on the waveform and wavelength of laser light and output of laser irradiation. The reasons for that are described later.

A black-oxide treatment is preferred to be conducted on conductive paste (13a) prior to laser irradiation.

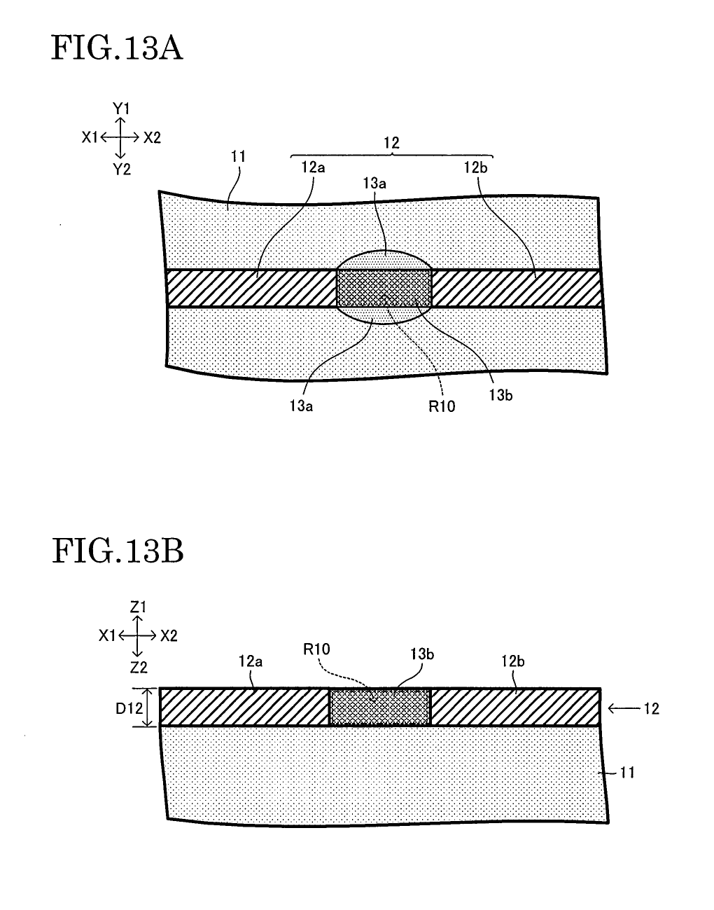

According to the above laser irradiation, the portion of conductive paste (13a) irradiated by laser light (only the portion positioned in space (R10) in the present embodiment) is sintered as shown in FIG. 13A and FIG. 13B (cross-sectional view of FIG. 13A). Hereinafter, the unsintered conductive paste is referred to as conductive paste (13a), and sintered conductive paste as conductive paste (13b).

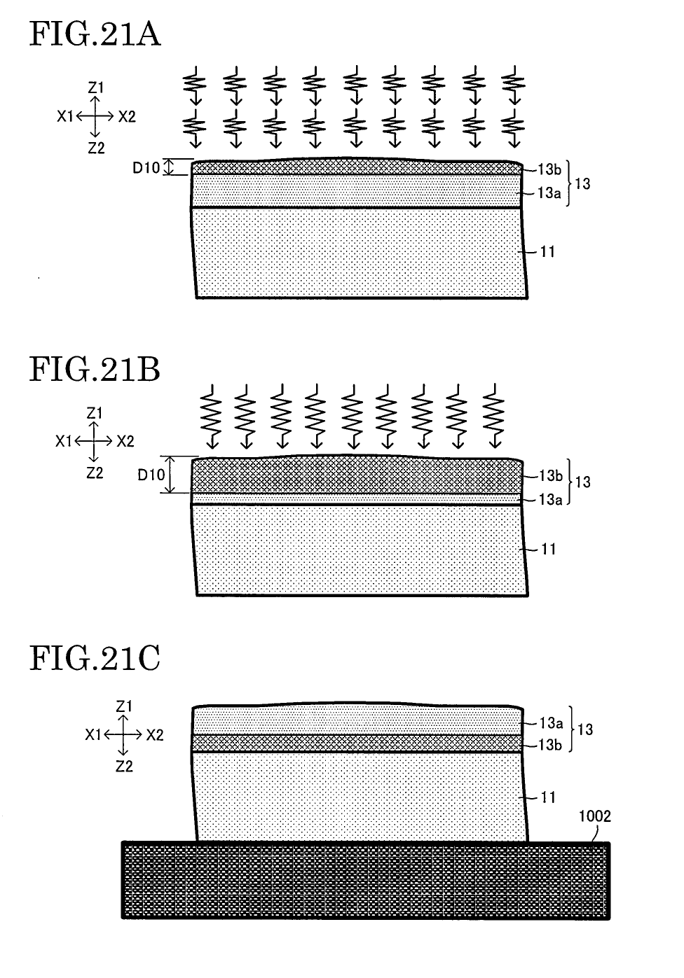

In the present embodiment, substantially the entire conductive paste (13a) positioned in space (R10) is sintered by laser irradiation and becomes conductive paste (13b). However, that is not the only option, and only part of conductive paste (13a) positioned in space (R10) (for example, only its surface portion) may be sintered by irradiating laser light (see later-described FIG. 21A or 21B).

The distance between conductive particles in the conductive paste is reduced by sintering. Namely, the distance between conductive particles in sintered conductive paste (13b) is smaller than the distance between conductive particles in unsintered conductive paste (13a). Also, volume contraction of the conductive paste occurs because of sintering (see FIGS. 12B and 13B).

Conductive paste (13b) is porous. Specifically, conductive particles in conductive paste (13a) are aggregated through sintering so that the paste becomes porous. When conductive paste (13b) becomes porous after sintering, volume contraction is thought to be suppressed.

In the present embodiment, the ratio of volume contraction by sintering is approximately 50%. When the volume before contraction is set as (V0) and the volume after contraction as (V1), the following definition is provided.

ratio of volume contraction=(V0−V1)/V0

The ratio of volume contraction by sintering conductive paste (13a) is preferred to be 0.6 or smaller. Using conductive paste (13a) having such a volume contraction ratio, it is easier to increase the thickness of wiring (conductive paste (13b)) to be formed in space (R10) (disconnected portion, for example). Also, cracking due to volume contraction is thought to be suppressed.

In the present embodiment, wiring (conductive paste (13b)) having substantially the same thickness (thickness (D12), for example) as conductive pattern (12a) or (12b) is formed in space (R10) between conductive patterns (12a) and (12b) (see FIG. 13B). However, that is not the only option, and the thickness of conductive paste (13b) may be set greater than thickness (D12) of conductive pattern (12a) or (12b), for example. From the viewpoint of conductive resistance, it is preferred that the thickness (the maximum value if not uniform) of the conductor in the repaired disconnected portion (conductive paste (13b)) after sintering be set at 12 μm or greater.

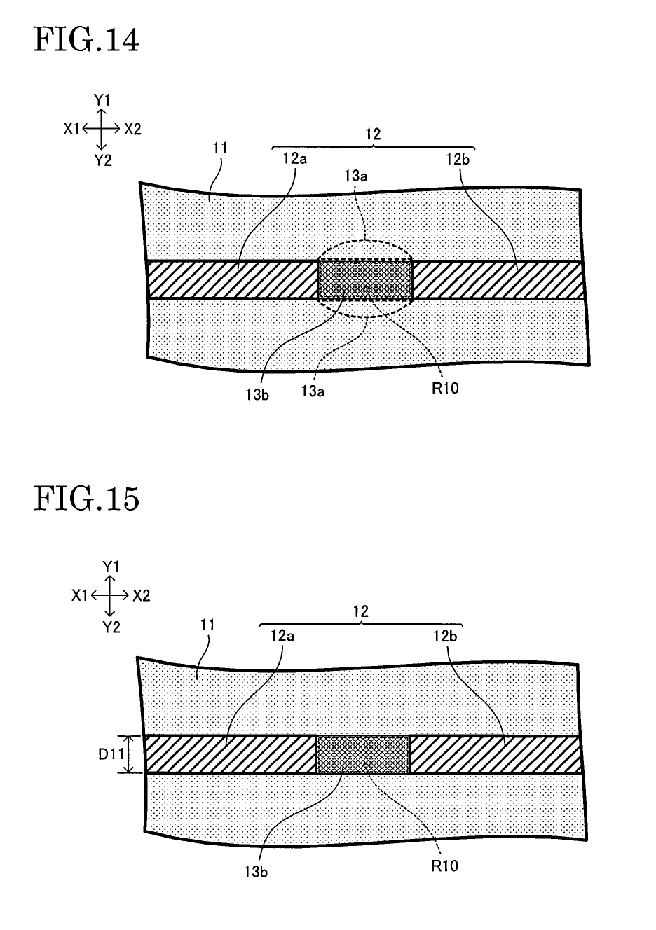

In step (S14) of FIG. 1, unsintered conductive paste (13a) is removed by cleansing with a solvent, for example, as shown in FIG. 14. Accordingly, wiring (conductive paste (13b)) with substantially the same width (width (D11), for example) as conductive pattern (12a) or (12b) is formed in space (R10) between conductive patterns (12a) and (12b) as shown in FIG. 15.

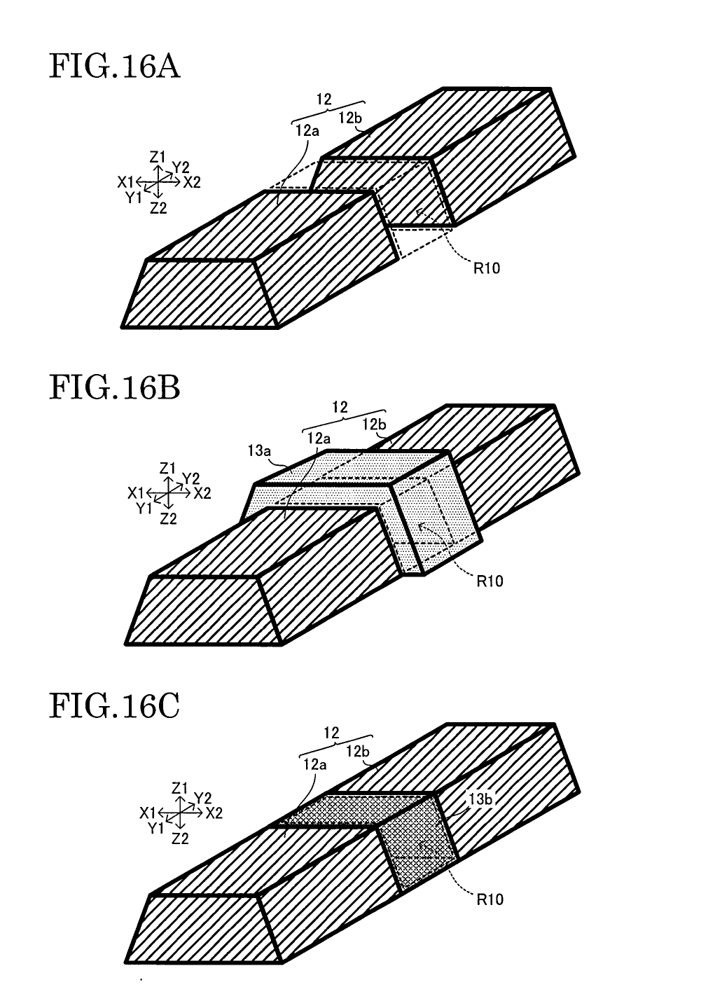

In the method for forming wiring in a wiring board according to the present embodiment, conductive patterns (12a, 12b) are formed on an insulation layer as shown in FIG. 16A. Then, as shown in FIG. 16B, conductive paste (13a) made of conductive particles and a binder is formed in space (R10) between conductive patterns (12a) and (12b), and laser light is irradiated on conductive paste (13a). Accordingly, sintered conductive paste (13b) is formed in space (R10) (disconnected portion) between conductive patterns (12a) and (12b) as shown in FIG. 16C. When irradiating laser light according to the present embodiment, the thickness of sintered conductive paste (13b) (the maximum value if not uniform) is set at 12 μm or greater (12 μm, for example). In so setting, resistance improves at the repaired disconnected portion.

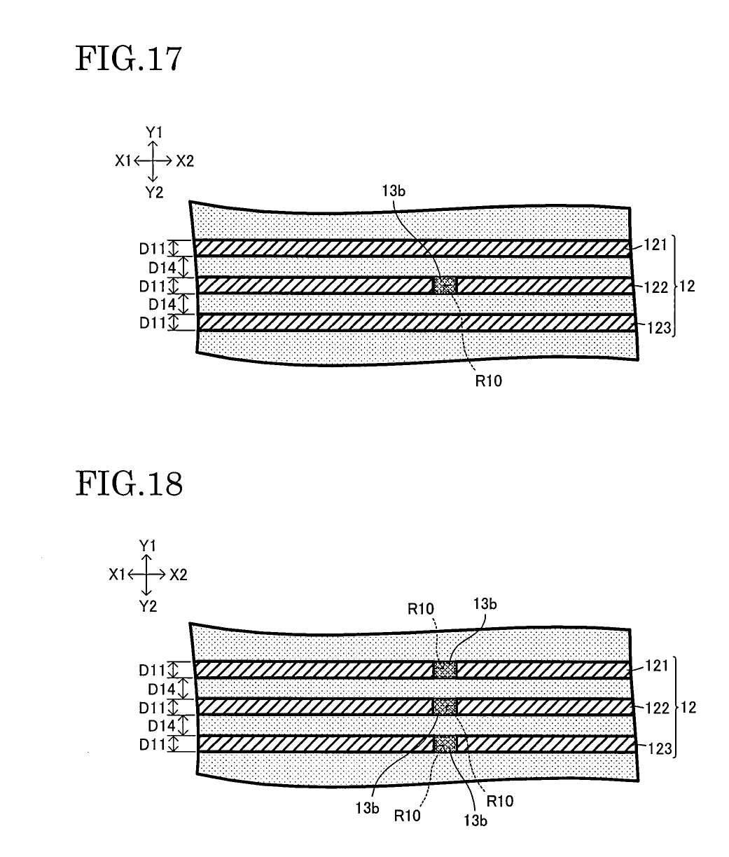

In a wiring board shown in FIG. 17, for example, conductive layer 12 formed on insulation layer 11 includes multiple wiring lines (121, 122, 123). Wiring lines (121, 122, 123) each have width (D11) and are arrayed parallel to each other at distance (D14). When wiring line 122 positioned between wiring lines 121 and 123 is disconnected in such a wiring board, space (R10) (disconnected portion) of wiring line 122 is repaired by the method for forming wiring in a wiring board according to the present embodiment (see FIG. 1 and others). When wiring lines (121, 122, 123) are each disconnected as shown in FIG. 18, spaces (R10) (disconnected portions) in wiring lines (121, 122, 123) respectively are also repaired. In this case, the disconnected portion of each wiring line may be repaired separately, or simultaneously (processed at the same time). Here, width (D11) is 50 μm, for example, and distance (D14) is 50 μm, for example.

In the method for forming wiring in a wiring board according to the present embodiment, the water, binder and the like between conductive particles in conductive paste (13a) are removed through sintering, causing volume contraction of conductive paste (13a). Namely, unlike the conductive paste that is cured without being sintered (unsintered conductive paste), sintered conductive paste (13b) contains almost no binder (resin). Therefore, the electric resistance (specific resistance, for example) of sintered conductive paste (13b) (repaired wiring line) is thought to be lower than the electric resistance (specific resistance, for example) of unsintered conductive paste. Therefore, using the method for forming wiring in a wiring board according to the present embodiment, wiring with excellent electrical characteristics (especially at the connected portion) is formed. Especially, a new wiring line is formed by such a method for forming wiring at the disconnected portion in a wiring board so that the disconnected portion is repaired according to the present embodiment. Thus, it is easier to achieve excellent electrical characteristics in the repaired portion (conductive paste (13b)) after the disconnected portion is repaired.

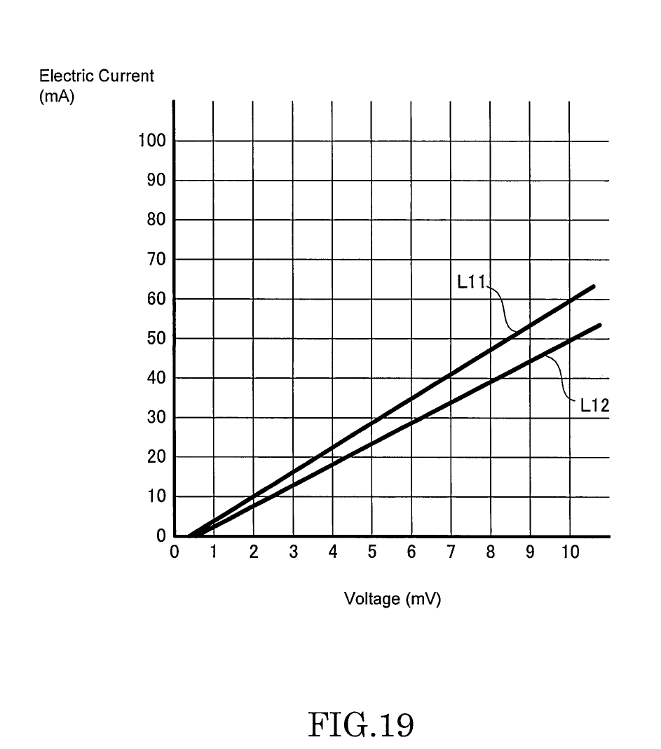

FIG. 19 shows the relationships between electric current and voltage respectively in an undisconnected portion (copper wiring) and a repaired portion (conductive paste) in one wiring line formed by the method for forming wiring in a wiring board according to the present embodiment. In FIG. 19, line (L11) indicates electrical characteristics of the undisconnected portion and line (L12) indicates electrical characteristics of the repaired portion. The data shown in FIG. 19 are obtained by measuring the electrical characteristics of wiring with a length of 10 mm, a width of 100 μm and a thickness of 12 μm.

When conductive paste (silver paste, for example) is cured without sintering, the electric resistance (specific resistance, for example) of the unsintered conductive paste has 25˜50 times the electric resistance (specific resistance, for example) of copper wiring.

By contrast, in the present embodiment, the electric resistance of an undisconnected portion of wiring (conductive pattern (12a) or (12b)) was 173 mΩ, and the electric resistance of the repaired portion of wiring (conductive paste (13b)) was 206 mΩ, as shown in FIG. 19. The electric resistance of the repaired portion (sintered conductive paste) was approximately 19% greater than the electric resistance of the undisconnected portion, and was lower than the electric resistance of the conductive paste that was cured without being sintered (unsintered conductive paste). As found above, the electric resistance (specific resistance, for example) of sintered conductive paste (13b) (repaired wiring) is thought to be lower than the electric resistance (specific resistance, for example) of unsintered conductive paste.

The electric resistance (specific resistance, for example) of the repaired portion (conductive paste (13b)) is preferred to be 1.2˜5.0 times the electric resistance (specific resistance, for example) of the undisconnected portion (conductive pattern (12a) or (12b)). When the repaired portion and the undisconnected portion in one wiring line have electric resistance closer to each other, it is thought that voltage is less likely to be concentrated in the repaired portion and that the electrical characteristics, durability or the like of the wiring line are improved.

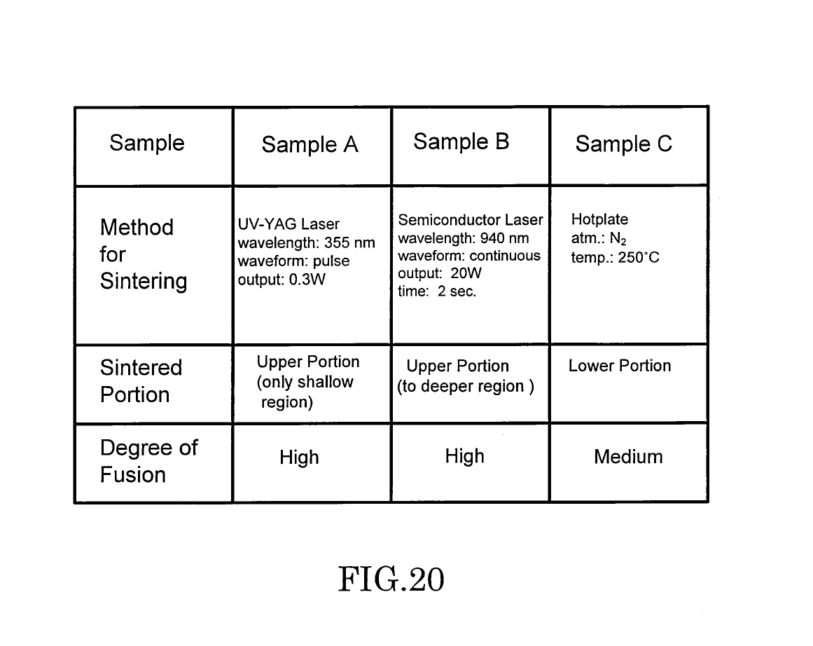

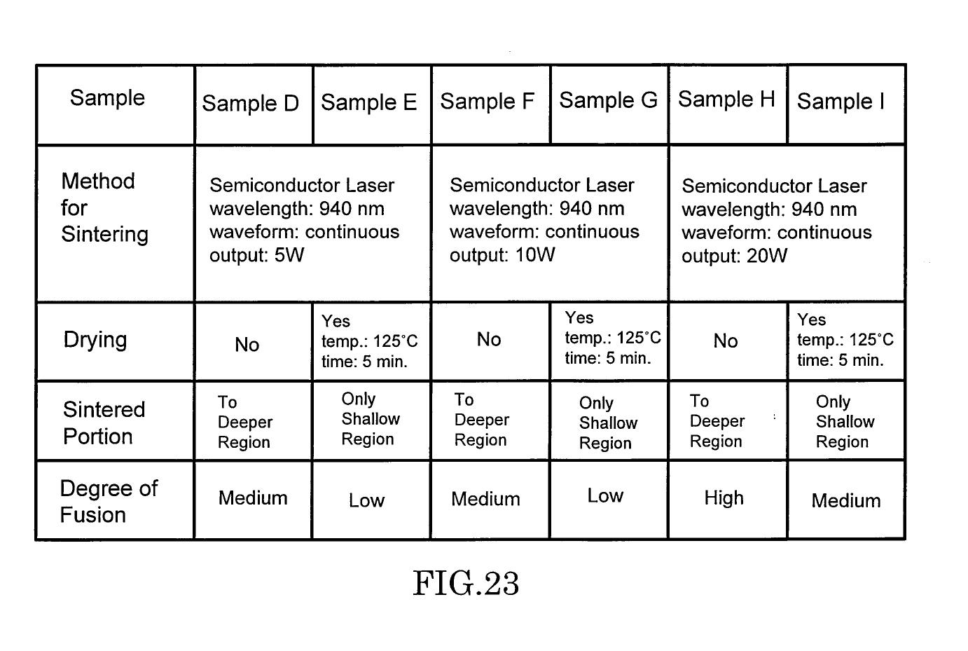

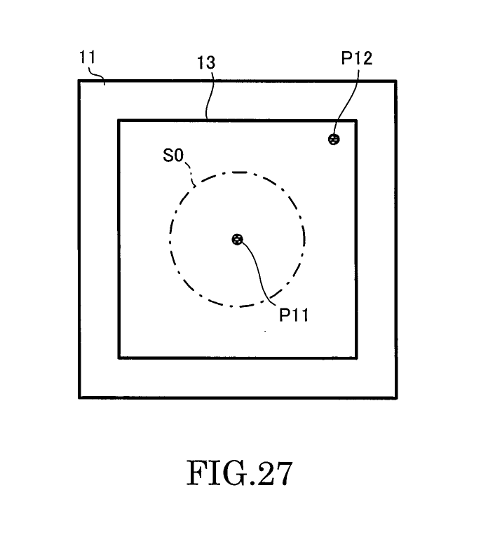

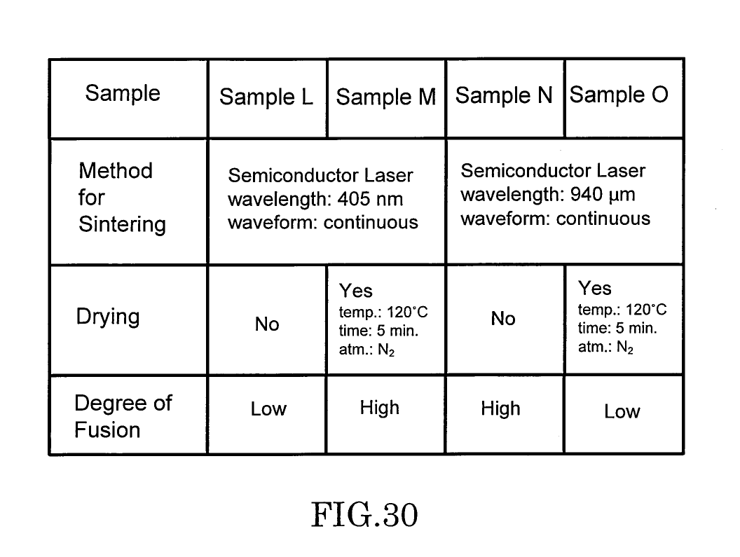

The following explains Tests 1˜4 which are conducted to examine how sintered states vary depending on sintering conditions when conductive paste is sintered. FIGS. 20˜22C are views illustrating Test 1; FIGS. 23˜26B are views illustrating Test 2; FIGS. 27˜29 are views illustrating Test 3; and FIGS. 30˜32B are views illustrating Test 4.

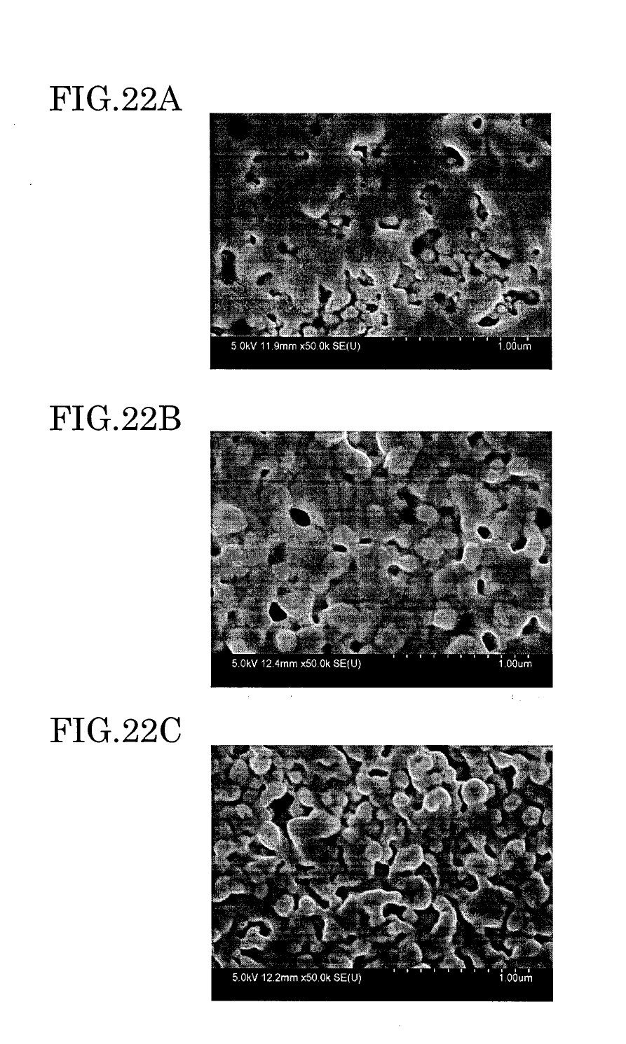

FIG. 20 is a table showing Samples A˜C and test results (evaluations) of each sample in Test 1. FIGS. 21A˜21C are views respectively illustrating methods for sintering Samples A˜C. FIGS. 22A˜22C are SEM photographs respectively showing the sintered states of Samples A˜C.

The methods for sintering Samples A˜C are shown respectively in FIGS. 21A˜21C. Samples A˜C are conductive pastes 13 obtained by sintering unsintered conductive paste under different conditions from each other. Conductive paste sintered in Test 1 (unsintered conductive paste) is formed by applying silver paste on insulation layer 11 made of glass epoxy and by drying it at 120° C. in N₂ atmosphere for five minutes. The size of insulation layer 11 is approximately 3 mm square, the thickness of insulation layer 11 is approximately 60 μm, and the thickness of the unsintered conductive paste is approximately 40 μm.

In the method for sintering Sample A, a UV-YAG laser is used as a light source to irradiate conductive paste under atmospheric pressure by laser light of 355 nm wavelength, 0.3 W output and 40 kHz frequency as shown in FIGS. 20 and 21A. During that time, the waveform of irradiated laser light is set to be a pulse wave of 30 ns pulse width and 10 μm pitch.

In the method for sintering Sample B, a semiconductor laser is used as light source to irradiate conductive paste under atmospheric pressure by laser light of 940 nm wavelength and 20 W output as shown in FIGS. 20 and 21B. During that time, the waveform of irradiated laser light is set to be continuous for 2 seconds per shot.

In the method for sintering Sample C, a hotplate is used to heat conductive paste from the insulation layer 11 side under N₂ atmosphere at 120° C. for 5 minutes as shown in FIGS. 20 and 21C.

Thicknesses of Samples A˜C (sintered conductive pastes 13) were each approximately 20 μm.

Regarding Sample A, only a shallower region of the upper portion of conductive paste 13 is sintered to become conductive paste (13b) as shown in FIG. 21A. Specifically, since the laser light has pulse waves with a wavelength in a UV range, the laser light is absorbed by conductive particles (Ag) on the surface of conductive paste 13, and fusion progresses. As shown in FIG. 22A, the degree of fusion is great in the laser absorption region of Sample A (at the shallower region of the upper portion).

Regarding Sample B, the upper portion of conductive paste 13 is sintered to a deeper region to become conductive paste (13b), as shown in FIG. 21B. Specifically, since the laser light has continuous waves of a relatively long wavelength, heat conduction is thought to be continuous among conductive particles (Ag). The laser light is thought to be absorbed by the binder. Fusion is thought to progress to the inner portion of conductive paste 13 through heat conduction. As shown in FIG. 22B, the degree of fusion is great in the laser absorption region of Sample B (to a deeper region of the upper portion).

Regarding Sample C, the lower portion of conductive paste 13 is sintered to become conductive paste (13b), as shown in FIG. 21C. Specifically, heat produced by the hotplate is conducted to conductive paste 13 through insulation layer 11, and fusion progresses at the lower portion of conductive paste 13. As shown in FIG. 22C, the degree of fusion at the heated region (lower portion) of Sample C is lower than Samples A and B.

From the results of Test 1 above, the degree of fusion of sintered conductive paste is thought to be greater when conductive paste is sintered by irradiating laser light than when conductive paste is sintered by heating using a hotplate (see FIGS. 20 and others). Thus, when conductive paste is sintered by irradiating laser light, it is thought to be easier to reduce electric resistance of the sintered conductive paste.

In addition, it is thought to be easier to sinter to the inner portion of conductive paste (to a deeper region of conductive paste) if continuous waves rather than pulse waves, and longer wavelengths rather than shorter wavelengths, are used (see FIGS. 20 and others). When the inner portion of conductive paste (a deeper region) is sintered, the electric resistance of wiring (conductive paste 13) is thought to be easier to reduce.

Conductive paste 13 is preferred to be sintered at least to a depth of 5 μm from the surface irradiated by laser light. Namely, in FIG. 21A or 21B, thickness (D10) of conductive paste (13b) is preferred to be 5 μm or greater. In Sample A (see FIG. 21A), thickness (D10) of conductive paste (13b) is 0.3 for example, and in Sample B (see FIG. 21B), thickness (D10) of conductive paste (13b) is 20 μm, for example,

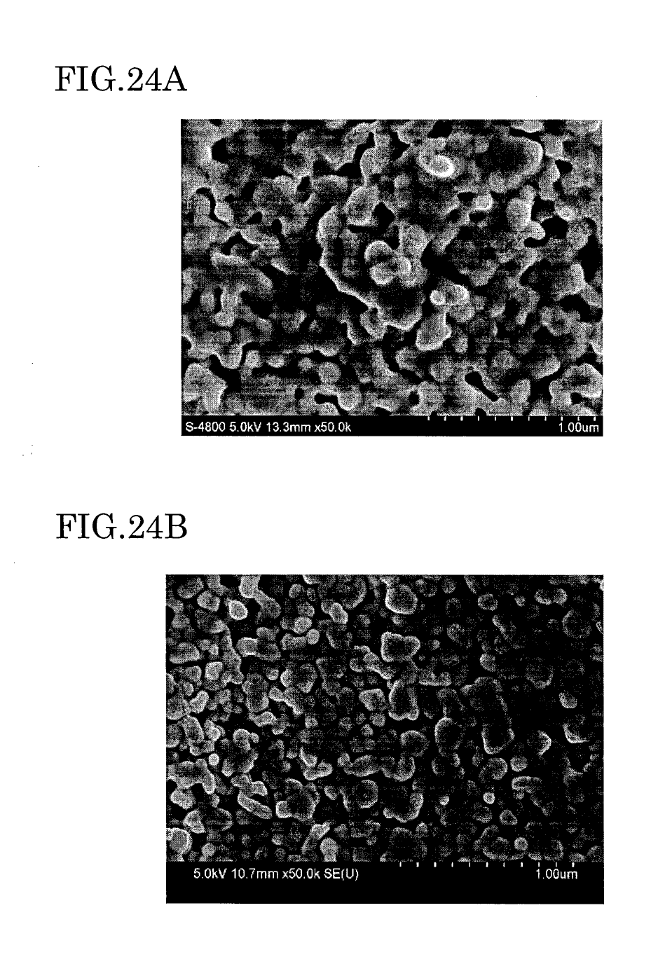

FIG. 23 is a table showing Samples D˜I and test results (evaluations) of each sample in Test 2. FIGS. 24A, 24B, 25A, 25B, 26A and 26B are SEM photographs respectively showing the sintered states of Samples D˜I.

Samples D˜I are conductive pastes obtained by sintering unsintered conductive paste under different conditions from each other. Conductive paste sintered in Test 2 (unsintered conductive paste) is made of silver paste, and is formed on an insulation layer. The insulation layer is made of glass epoxy. The size of the insulation layer is approximately 3 mm square, the thickness of the insulation layer is approximately 60 μm, and the thickness of unsintered conductive paste is approximately 40 μm.

The methods for sintering Samples D˜I are shown in FIG. 23. In any of the sintering methods of Samples D˜I, a semiconductor laser is used as a light source to irradiate conductive paste by laser light of 940 nm wavelength under atmospheric pressure. During that time, the waveform of laser light for irradiation is set to be continuous for 2 seconds per shot.

Here, laser light is irradiated at the conductive paste at 5 W output in the sintering method of Samples D and E; laser light is irradiated at the conductive paste at 10 W output in the sintering method of Samples F and G; and laser light is irradiated at the conductive paste at 20 W output in the sintering method of Samples H and I.

In addition, in any method for sintering Samples D, F and H, conductive paste is not dried prior to laser irradiation. In any method for sintering Samples E, G and I, conductive paste is dried under N₂ atmosphere at 120° C. for 5 minutes prior to laser irradiation.

Regarding Samples D, F and H, the upper portion of conductive paste is sintered to a deeper region. Specifically, since the conductive paste was not dried, a certain amount of binder is contained and laser light is thought to be absorbed by the binder. Thus, the binder facilitates heat conduction, and fusion is thought to progress to the inner portion of conductive paste through heat conduction.

Regarding Samples E, G and I, only a shallower region of the upper portion is sintered. Specifically, since the conductive paste was dried, the binder is removed. Thus, fusion is thought to occur only in a shallower region of the upper portion.

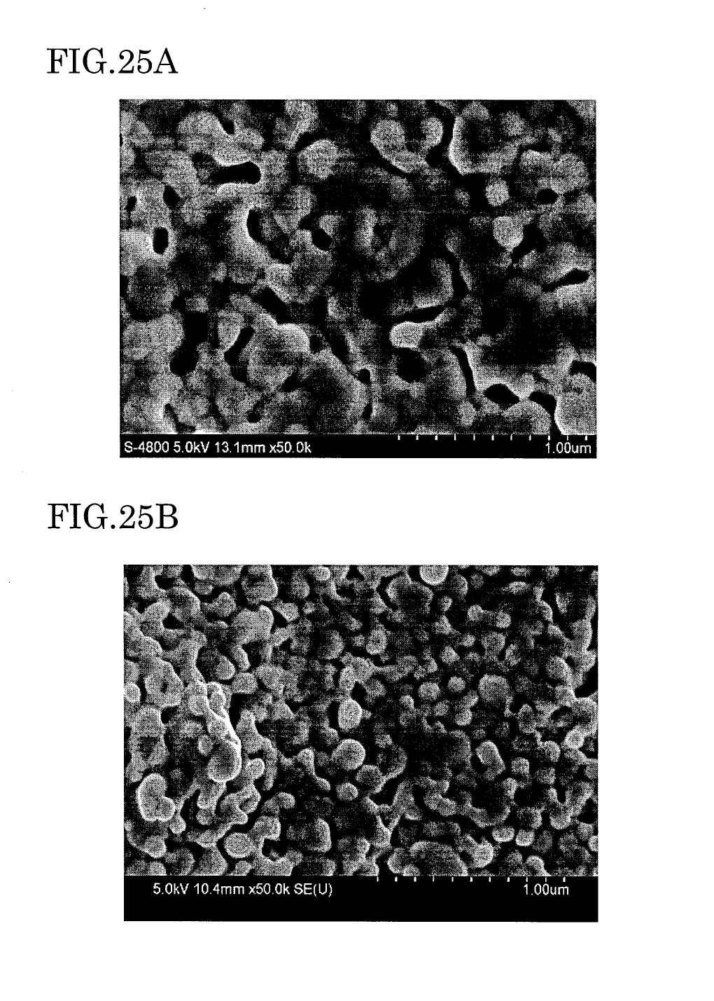

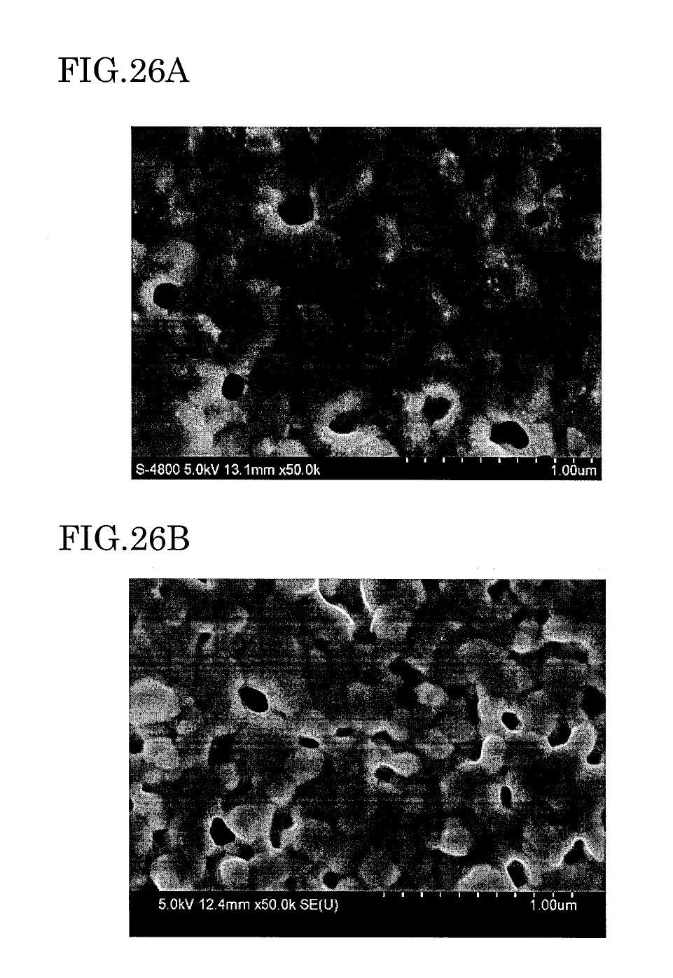

As shown in FIGS. 24A and 24B, the degree of fusion of Sample D (see FIG. 24A) is greater than the degree of fusion of Sample E (see FIG. 24B); as shown in FIGS. 25A and 25B, the degree of fusion of Sample F (see FIG. 25A) is greater than the degree of fusion of Sample G (see FIG. 25B); and as shown in FIGS. 26A and 26B, the degree of fusion of Sample H (see FIG. 26A) is greater than the degree of fusion of Sample I (see FIG. 26B).

From the results in Test 2 above, if sintered without being dried rather than being sintered after being dried, it is thought that the degree of fusion of sintered conductive paste tends to be greater and that it is easier to sinter to the inner portion of conductive paste (to a deeper region) (see FIGS. 23 and others). Therefore, when conductive paste is irradiated by laser light (sintered) without being dried, it is thought to be easier to reduce the electric resistance of sintered conductive paste.

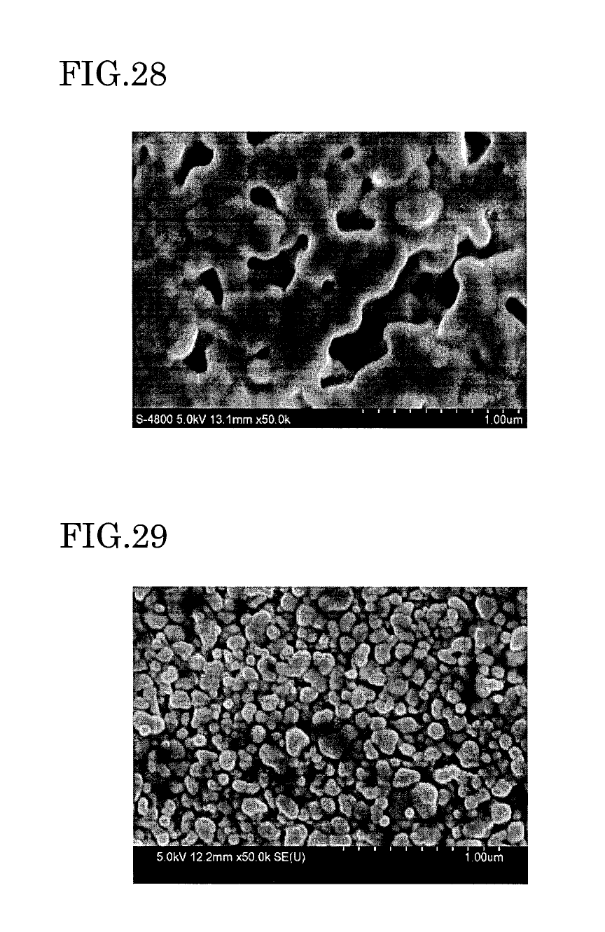

FIG. 27 is a view illustrating Test 3. FIGS. 28 and 29 are SEM photographs respectively showing the sintered states of Samples J and K in Test 3.

In Test 3, by irradiating laser light at the central portion of unsintered conductive paste (see laser spot (S0) in FIG. 27), at least part of the conductive paste is sintered. then, the degree of fusion or the like is measured in sintered conductive paste 13 (Samples J and K). Specifically, SEM photographs are taken respectively at first detection spot (P11) positioned in the central portion of sintered conductive paste 13 (Samples J and K) (in particular, the center of laser spot (S0)), and at second detection spot (P12) positioned at an edge of sintered conductive paste 13 (Samples J and K) (in particular, outside laser spot (S0)).

Unsintered conductive paste for Sample J is prepared the same as for Sample H, and the conductive paste is irradiated by laser light under the same conditions as Sample H when sintering Sample J. The sintered state of Sample J at first detection spot (P11) (the center of laser spot (S0)) is shown in previous FIG. 26A. Also, the sintered state of Sample J at second detection spot (P12) (outside laser spot (S0)) is shown in FIG. 28. As shown in FIGS. 26A and 28, the degree of fusion of Sample J at second detection spot (P12) (see FIG. 28) is lower than the degree of fusion of Sample J at first detection spot (P11) (see FIG. 26A).

Unsintered conductive paste for Sample K is prepared the same as for Sample I, and the conductive paste is irradiated by laser light under the same conditions as Sample I when sintering Sample K. The sintered state of Sample K at first detection spot (P11) (the center of laser spot (S0)) is shown in previous FIG. 26B. Also, the sintered state of Sample K at second detection spot (P12) (outside laser spot (S0)) is shown in FIG. 29. As shown in FIGS. 26B and 29, the degree of fusion of Sample K at second detection spot (P12) (see FIG. 29) is lower than the degree of fusion of Sample K at first detection spot (P11) (see FIG. 26B).

From the results of Tests 2 and 3 above, when conductive paste is sintered by irradiating laser light, if the output of laser irradiation is greater and if the portion closer to the laser spot is irradiated, the degree of fusion of conductive paste is thought to be greater (see FIGS. 23 and 27˜29).

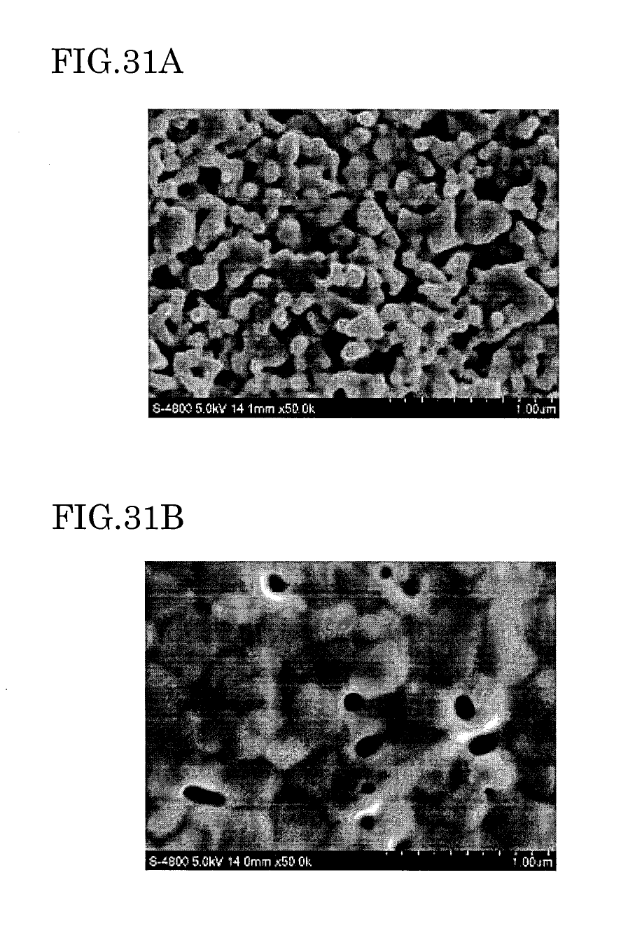

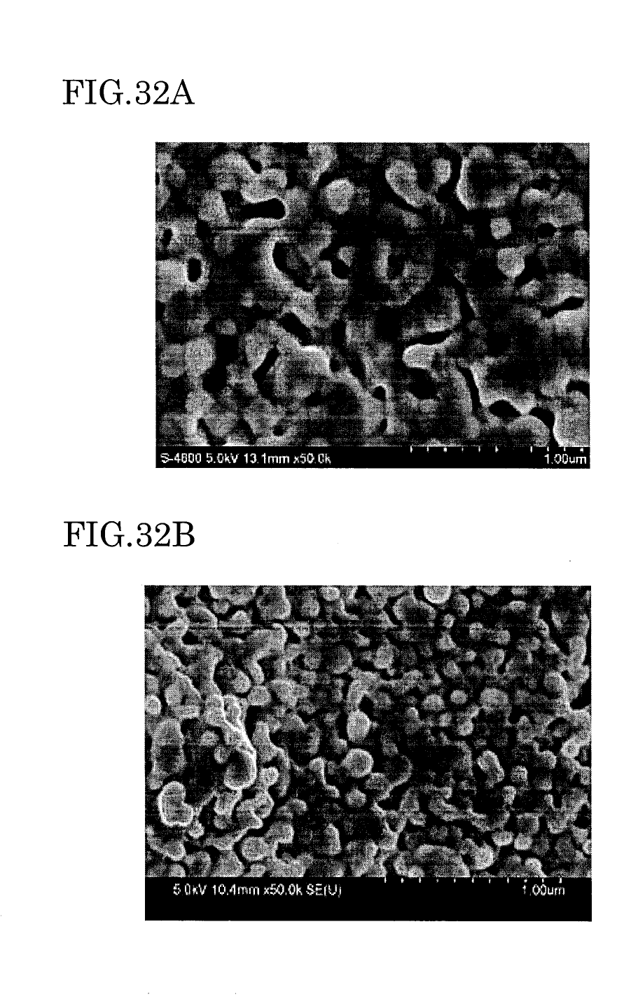

FIG. 30 is a table showing Samples L˜O and test results (evaluations) of each sample in Test 4. FIGS. 31A, 31B, 32A and 32B are SEM photographs respectively showing the sintered states of Samples L˜O.

Samples L˜O are conductive pastes obtained by sintering unsintered conductive paste under different conditions from each other. Conductive paste sintered in Test 4 (unsintered conductive paste) is made of silver paste, and is formed on an insulation layer. The insulation layer is made of glass epoxy. The size of the insulation layer is approximately 3 mm square, the thickness of the insulation layer is approximately 60 μm, and the thickness of the unsintered conductive paste is approximately 40 μm.

The sintering methods of Samples L˜O are shown in FIG. 30. In any of the sintering methods of Samples L˜O, a semiconductor laser is used as a light source to irradiate conductive paste by laser light at 20 W output under atmospheric pressure. During that time, the waveform of laser light for irradiation is set to be continuous for 2 seconds per shot.

Here, in the sintering method of Samples L and M, laser light of wavelength 405 nm is irradiated at the conductive paste, and in the sintering method of Samples N and O, laser light of wavelength 940 μm is irradiated at the conductive paste.

In addition, in the sintering methods of Samples L and N, conductive paste is not dried prior to laser irradiation. In the sintering methods of Samples M and O, conductive paste is dried under N₂ atmosphere at 120° C. for 5 minutes prior to laser irradiation.

The sintered state of Sample L is shown in FIG. 31A; the sintered state of Sample M is shown in FIG. 31B; the sintered state of Sample N is shown in FIG. 32A; and the sintered state of Sample O is shown in FIG. 32B. As shown in FIGS. 31A and 32B, fusion is considered to be hard to advance in Samples L and O. By contrast, a greater degree of fusion was obtained in Samples M and N as shown in FIGS. 31B and 32A.

From the results of Test 4 above, the following are thought to be found.

It is thought that laser light of shorter wavelengths (ultraviolet range, for example) tends to be absorbed by conductive particles. Regarding Sample L which is not dried prior to laser irradiation, laser light is thought to be prevented from being absorbed by conductive particles (Ag) by non-conductive material (a binder, for example). On the other hand, regarding Sample M which is dried prior to laser irradiation, laser light is thought to be absorbed by conductive particles.

The method for forming wiring in a wiring board according to the present embodiment (or the method for repairing a disconnection in a wiring board) includes drying conductive paste (13a) after conductive paste (13a) is formed (step (S12) of FIG. 1) and before laser light is irradiated (step (S13) of FIG. 1). It is thought that laser light irradiated in step (S13) of FIG. 1 is preferred to be continuous waves in a wavelength range of 300 nm or greater but shorter than 700 nm. In addition, at the time of irradiating laser light, the amount of conductive particles (such as silver) contained in conductive paste (13a) is preferred to be in a range of 50 wt. % or greater, more preferably in a range of 70 wt. % or greater. By setting such a structure, the degree of fusion of sintered conductive paste is thought to increase (see FIGS. 30 and others). As a result, it is thought to be easier to reduce the electric resistance of sintered conductive paste.

On the other hand, it is thought that laser light of longer wavelengths (such as visible light range or infrared range) tends to be absorbed by non-conductive material (such as a binder) but is hard to be absorbed by conductive particles. Regarding Sample O which is dried prior to laser irradiation, since it contains less binder, it is thought that laser light is less likely to be absorbed by conductive paste. On the other hand, regarding Sample N which is not dried prior to laser irradiation, laser light is thought to be absorbed by the binder.

According to the method for forming wiring in a wiring board of the present embodiment (or the method for repairing a disconnection in a wiring board), laser light is irradiated (step (S13) of FIG. 1) after conductive paste (13a) is formed (step (S12) of FIG. 1) without drying conductive paste (13a). It is thought that laser light irradiated at step (S13) of FIG. 1 is preferred to have continuous waves with a wavelength in a range of 700 nm or greater. Also, at the time of laser irradiation, it is thought that the amount of binder contained in conductive paste (13a) is preferred to be in a range of 50 wt. % or greater, more preferably in a range of 70 wt. % or greater. According to such a structure, the degree of fusion of sintered conductive paste is thought to increase (see FIGS. 30 and the like). As a result, it is thought to be easier to reduce the electric resistance of sintered conductive paste.

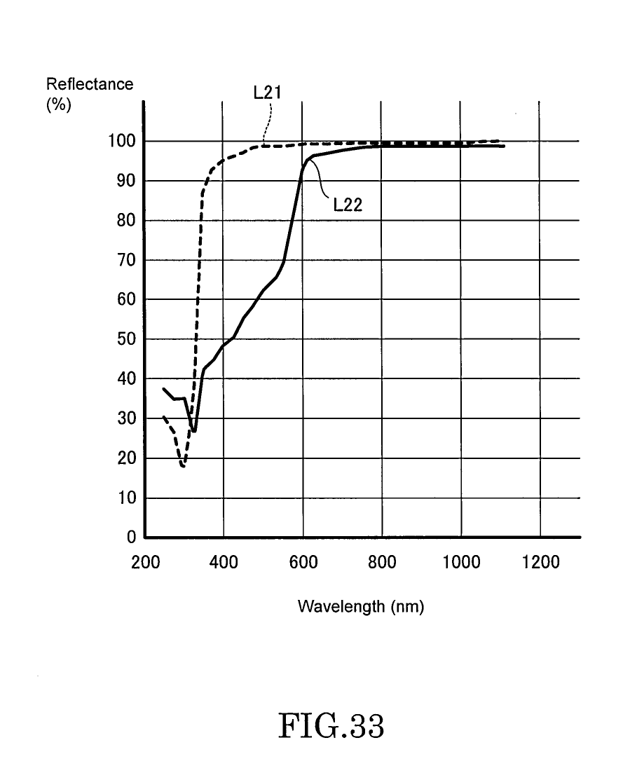

FIG. 33 shows relationships between wavelength and reflectance of Ag (silver) and Cu (copper) respectively. In FIG. 33, line (L21) indicates characteristics of Ag, and line (L22) indicates characteristics of Cu. The data shown in FIG. 33 are obtained by irradiating multiple kinds of laser light with different wavelengths on Ag (sputtered film) and Cu (sputtered film) respectively using a YAG laser, a semiconductor laser or the like.

As shown in FIG. 33, it is thought that Cu has a lower reflectance than Ag (or a higher absorption rate) to laser light with a 350˜700 nm wavelength, more specifically, with a 350˜600 nm wavelength. Therefore, when conductive paste is sintered based on light absorption of conductive particles (when the amount of binder at the time of sintering is reduced by drying, for example), it is thought that the degree of fusion tends to be greater in Cu than in Ag. Namely, to achieve a greater degree of fusion by sintering, conductive particles in conductive paste (13a) are preferred to be made of copper.

### Second Embodiment

A second embodiment of the present invention is described by focusing on differences from the above first embodiment. Here, the same numerical reference is used for the same element as that shown above in FIGS. 1˜15 and the like, and, for the common portions already described above, their descriptions are omitted or simplified.

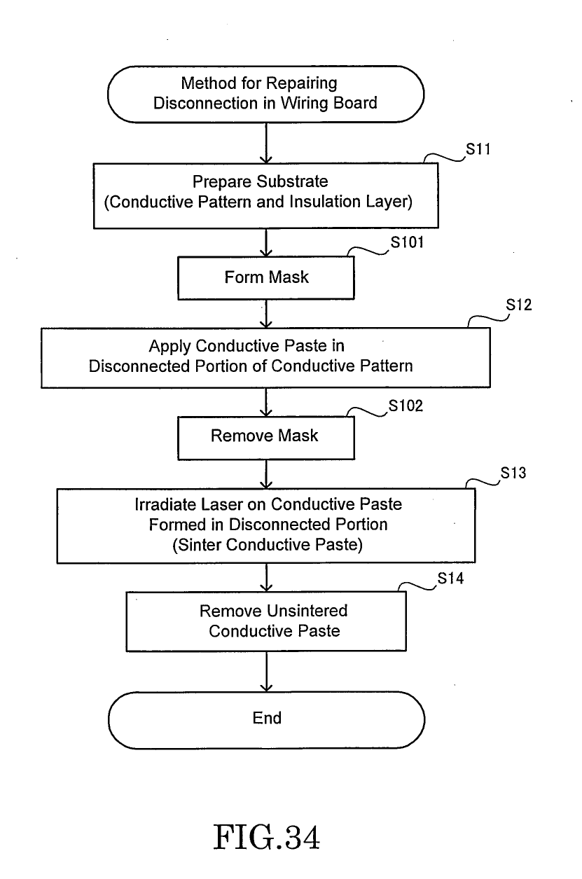

FIG. 34 schematically shows a method for forming wiring in a wiring board according to the present embodiment (a method for repairing a disconnection). In the present embodiment, a disconnection is repaired by forming wiring.

In step (S11) of FIG. 34, substrate 10 having insulation layer 11 and conductive layer 12 is prepared the same as in the first embodiment (step (S11) of FIG. 1). Conductive layer 12 is formed on insulation layer 11, and includes conductive patterns (12a, 12b). Space (R10) (disconnected portion) exists between conductive patterns (12a) and (12b).

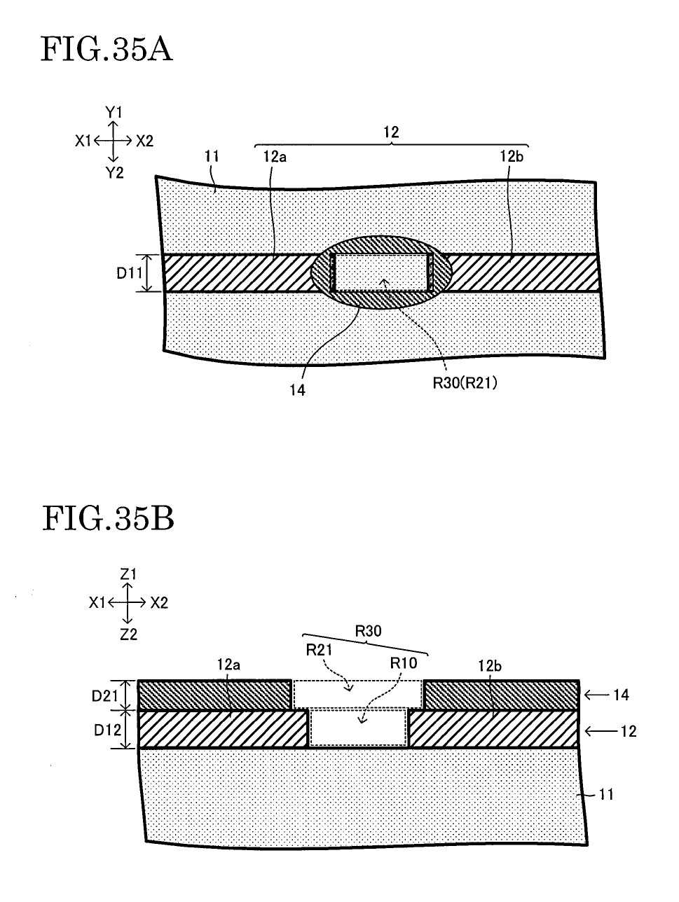

In step (S101) of FIG. 34, mask 14 is positioned to surround space (R10) as shown in FIG. 35A and FIG. 35B (cross-sectional view of FIG. 35A). Mask 14 has opening portion (R21) in the position corresponding to space (R10). Mask 14 is made of polycyanoacrylate, for example. In the present embodiment, liquid polycyanoacrylate is applied and cured by being dried. Then, opening portion (R21) is formed using a laser, for example.

In the present embodiment, part of mask 14 is positioned on conductive patterns (12a) and (12b) near space (R10). In particular, mask 14 is positioned on insulation layer 11, conductive pattern (12a) and conductive pattern (12b) (see FIG. 35A).

Since mask 14 has opening portion (R21) in a position corresponding to space (R10), opening portion (R21) of mask 14 and space (R10) become contiguous and form one opening portion (R30). In the present embodiment, the opening area of opening portion (R21) is greater than the opening area of space (R10). Then, end portions (upper and side surfaces) of conductive patterns (12a, 12b) respectively are exposed in opening portion (R30). The planar shape (X-Y plane) of opening portion (R21) and the planar shape (X-Y plane) of space (R10) may be symmetrical or asymmetrical.

Opening portion (R21) of mask 14 has substantially the same width (width (D11)) as conductive pattern (12a) or (12b), for example. Thickness (D21) of mask 14 (the average value if not uniform) is 8 μm, for example.

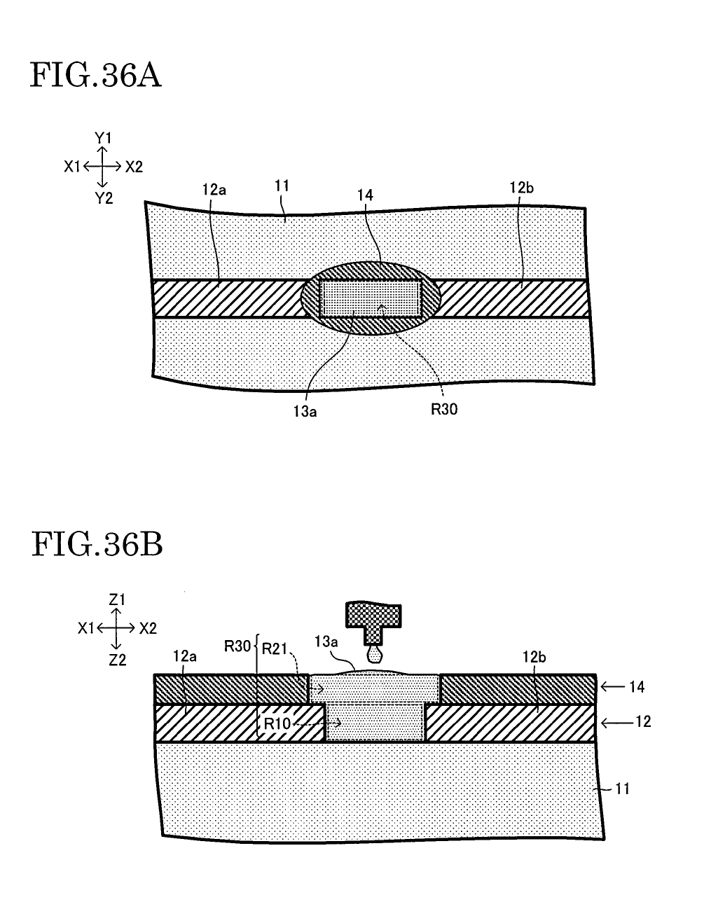

In step (S12) of FIG. 34, liquid conductive paste (13a) is formed (applied, for example) in opening portion (R30) between conductive patterns (12a) and (12b) as shown in FIG. 36A and FIG. 36B (cross-sectional view of FIG. 36A). Accordingly, conductive paste (13a) is formed in opening portion (R21) of mask 14 and space (R10) (disconnected portion). Also, since the opening area of opening portion (R21) of mask 14 is greater than the opening area of space (R10), conductive paste (13a) makes contact with both side and upper surfaces of conductive pattern (12a) or (12b). The thickness of conductive paste (13a) (the average value if not uniform) is substantially the same as the sum of thickness (D12) of conductive pattern (12a) or (12b) and thickness (D21) of mask 14, for example.

Since mask 14 is formed on conductive patterns (12a, 12b) in the present embodiment, it is easier to set the thickness of conductive paste (13a) (the average value if not uniform) before it is cured to be greater than any of conductive patterns (12a) and (12b).

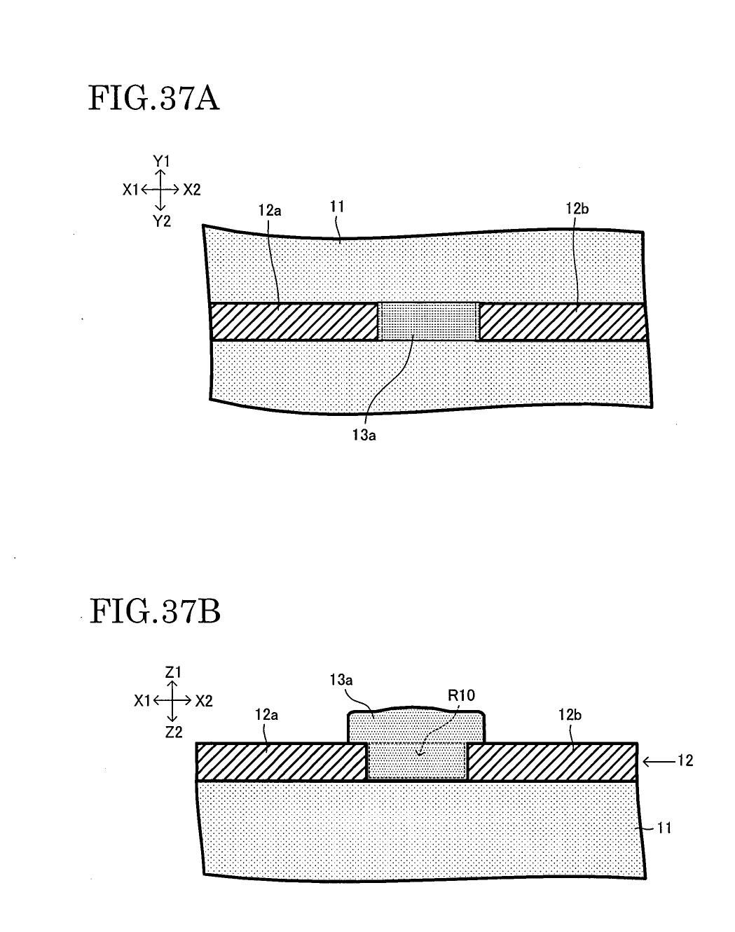

In step (S102) of FIG. 34, mask 14 is removed as shown in FIG. 37A and FIG. 37B (cross-sectional view of FIG. 37A). However, that is not the only option, and mask 14 may be removed after conductive paste (13a) is sintered.

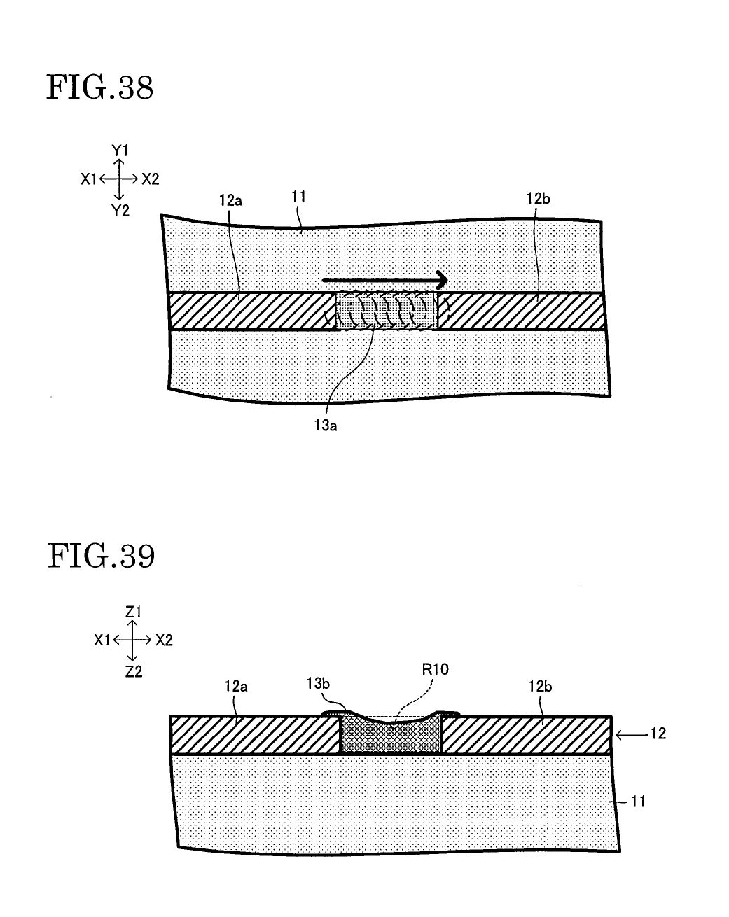

In step (S13) of FIG. 34, conductive paste (13a) is sintered by irradiating laser light the same as in the first embodiment (step (S13) of FIG. 1) as shown in FIG. 38. In doing so, unsintered conductive paste (13a) irradiated by laser light becomes porous conductive paste (13b) (sintered conductive paste) as shown in FIG. 39. In addition, sintering causes volume contraction (see FIGS. 37B and 39). Conductive paste (13b) makes contact with both side and upper surfaces of conductive pattern (12a) or (12b). In the present embodiment, conductive paste (13b) has substantially the same thickness as each of conductive patterns (12a, 12b). However, that is not the only option, and the thickness of conductive paste (13b) may be set greater than each thickness of conductive patterns (12a, 12b).

Then, if required, unsintered conductive paste (13a) is removed the same as in the first embodiment (step (S14) of FIG. 1).

According to the method for forming wiring in a wiring board of the present embodiment (or the method for repairing a disconnection in a wiring board), mask 14 is formed before forming conductive paste (13a), thus making it easier to form thick wiring (conductive paste (13a) or (13b)). As a result, it is easier to reduce the electric resistance of the connected wiring portion (such as the disconnected portion). Also, it is easier to use conductive paste (13a) with a higher rate of volume contraction.

Since conductive paste (13b) makes contact with both side and upper surfaces of conductive pattern (12a) or (12b) in the present embodiment, the contact area of conductive paste (13b) and conductive pattern (12a) or (12b) increases. Accordingly, it is easier to reduce the resistance at the interface of conductive paste (13b) and conductive pattern (12a) or (12b). Also, it is easier to enhance adhesive strength.

Regarding the structure and treatments the same as in the first embodiment, substantially the same effects as in the first embodiment described above are achieved in the present embodiment.

### Third Embodiment

A third embodiment of the present invention is described by focusing on differences from the above first embodiment. Here, the same numerical reference is used for the same element as that shown above in FIGS. 1˜15 and the like, and, for the common portions already described above, their descriptions are omitted or simplified.

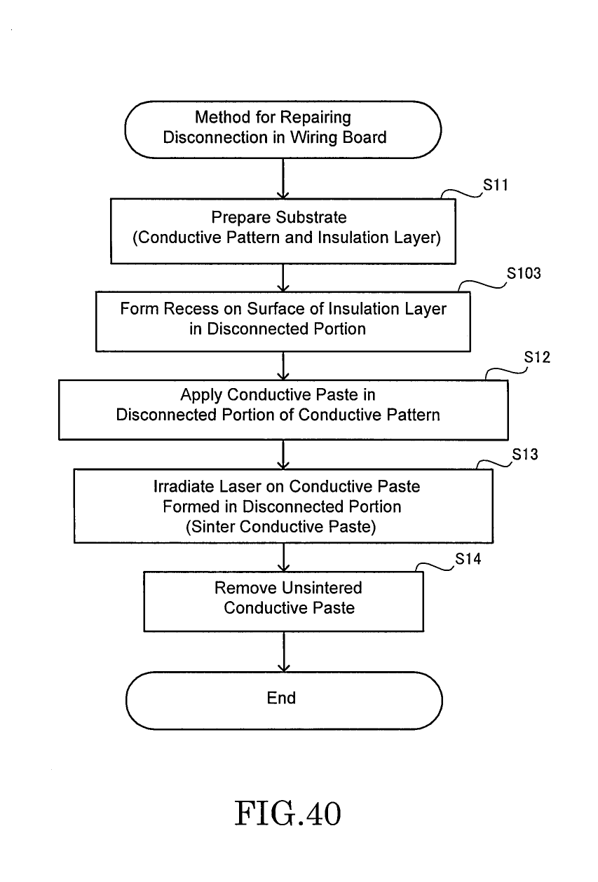

FIG. 40 schematically shows a method for forming wiring in a wiring board according to the present embodiment (a method for repairing a disconnection). In the present embodiment, a disconnection is repaired by forming wiring.

In step (S11) of FIG. 40, substrate 10 having insulation layer 11 and conductive layer 12 is prepared the same as in the first embodiment (step (S11) of FIG. 1). Conductive layer 12 is formed on insulation layer 11, and includes conductive patterns (12a, 12b). Space (R10) (disconnected portion) exists between conductive patterns (12a) and (12b).

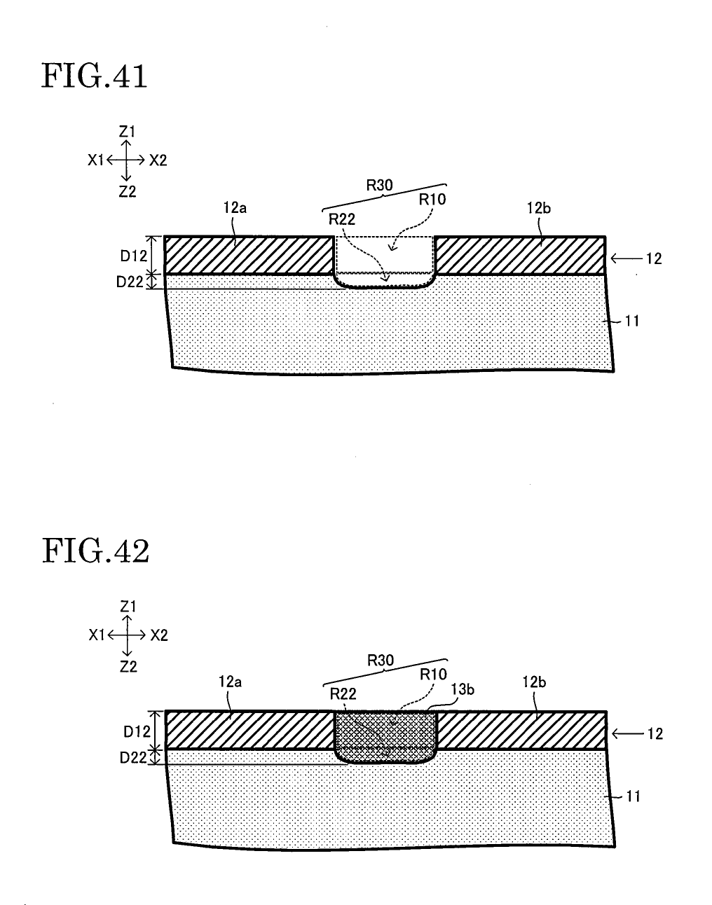

In step (S103) of FIG. 40, through etching or using a laser, for example, recess (R22) is formed on a surface of insulation layer 11 in space (R10) as shown in FIG. 41. Recess (R22) is formed in a position corresponding to space (R10). Space (R10) and recess (R22) become contiguous and form one opening portion (R30).

Space (R10) and recess (R22) have substantially the same planar shape (X-Y plane) as each other, for example. Depth (D22) of recess (R22) is 8 μm, for example.

In step (S12) of FIG. 40, conductive paste (13a) is formed the same as in the first embodiment (step (S12) of FIG. 1); in step (S13) of FIG. 40, conductive paste (13a) is sintered the same as in the first embodiment (step (S13) of FIG. 1); and in step (S14) of FIG. 40, unsintered conductive paste (13a) is removed the same as in the first embodiment (step (S14) of FIG. 1). In doing so, porous conductive paste (13b) (sintered conductive paste) is formed in opening portion (R30) between conductive patterns (12a) and (12b) as shown in FIG. 42. The thickness of conductive paste (13b) (average value if not uniform) is substantially the same as the sum of thickness (D12) of conductive pattern (12a) or (12b) and depth (D22) of recess (R22), for example.

According to the method for forming wiring in a wiring board of the present embodiment (or the method for repairing a disconnection in a wiring board), recess (R22) is formed before forming conductive paste (13a), thus making it easier to form thick wiring (conductive paste (13a) or (13b)). As a result, it is easier to reduce the electric resistance of the connected wiring portion (such as the disconnected portion). Also, it is easier to use conductive paste (13a) with a higher rate of volume contraction.

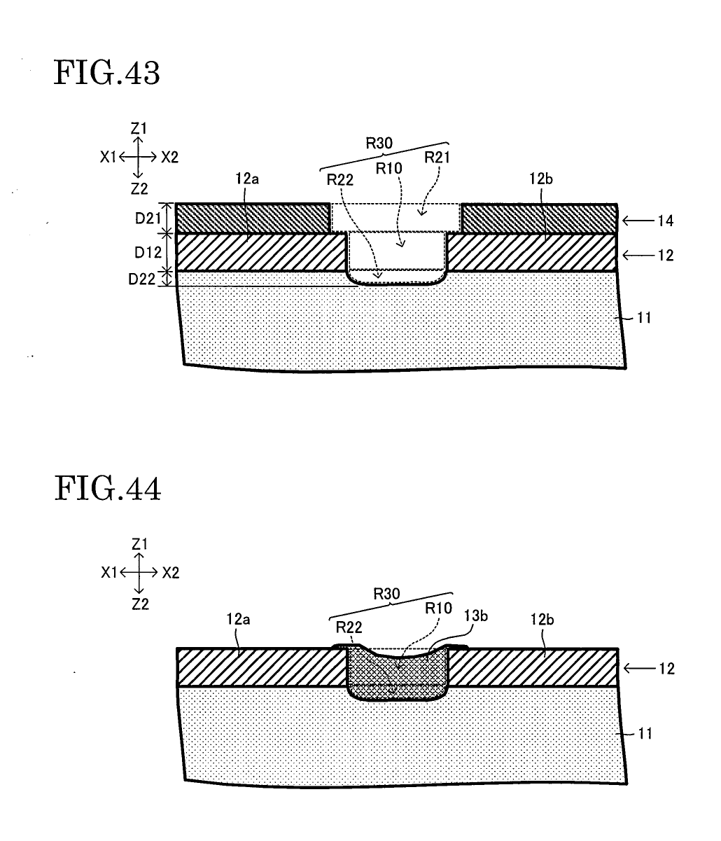

It is also an option to use both mask 14 described above (see the second embodiment) and recess (R22) of the present embodiment. For example, after recess (R22) is formed (step (S103) of FIG. 40), mask 14 which has opening portion (R21) in a position corresponding to space (R10) may be formed the same as in the second embodiment (step (S101) of FIG. 34) as shown in FIG. 43. Then, conductive paste (13a) is formed the same as in the first embodiment (step (S12) of FIG. 1), mask 14 is removed the same as in the second embodiment (step (S102) of FIG. 34), and conductive paste (13a) is sintered the same as in the first embodiment (step (S13) of FIG. 1). Accordingly, wiring (conductive paste (13b)) is formed in space (R10) (disconnected portion) between conductive patterns (12a) and (12b) as shown in FIG. 44.

According to such a method, it is easier to form thick wiring (conductive paste (13a) or (13b)). As a result, it is easier to reduce the electric resistance of the connected wiring portion (such as the disconnected portion). Also, it is easier to use conductive paste (13a) with a higher rate of volume contraction.

Regarding the structure and treatments the same as in the first and second embodiments, substantially the same effects as in the first and second embodiments described above are achieved in the present embodiment.

### Fourth Embodiment

A fourth embodiment of the present invention is described by focusing on differences from the above first embodiment. Here, the same numerical reference is used for the same element as that shown above in FIGS. 1˜15 and the like, and, for the common portions already described above, their descriptions are omitted or simplified.

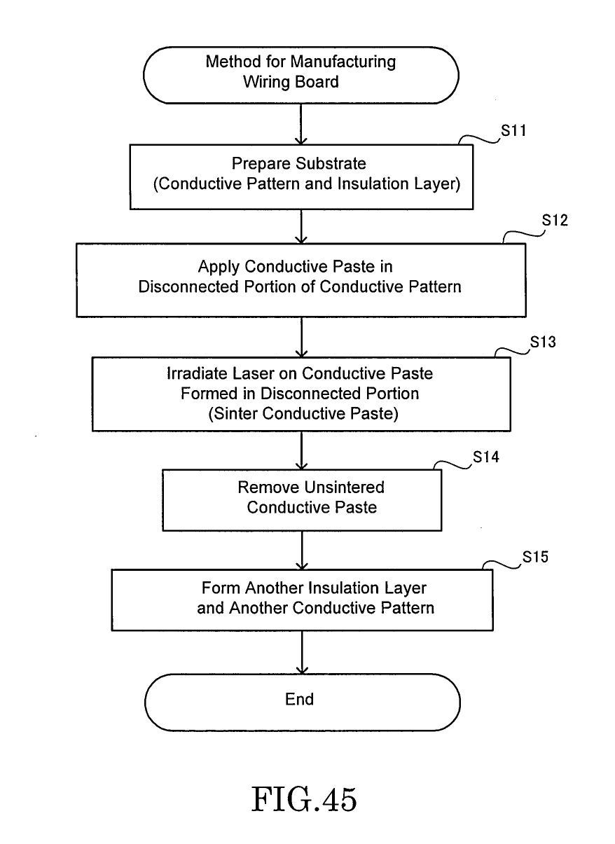

FIG. 45 schematically shows a method for manufacturing a wiring board according to the present embodiment. In the present embodiment, a wiring board is manufactured by the methods of forming wiring described above.

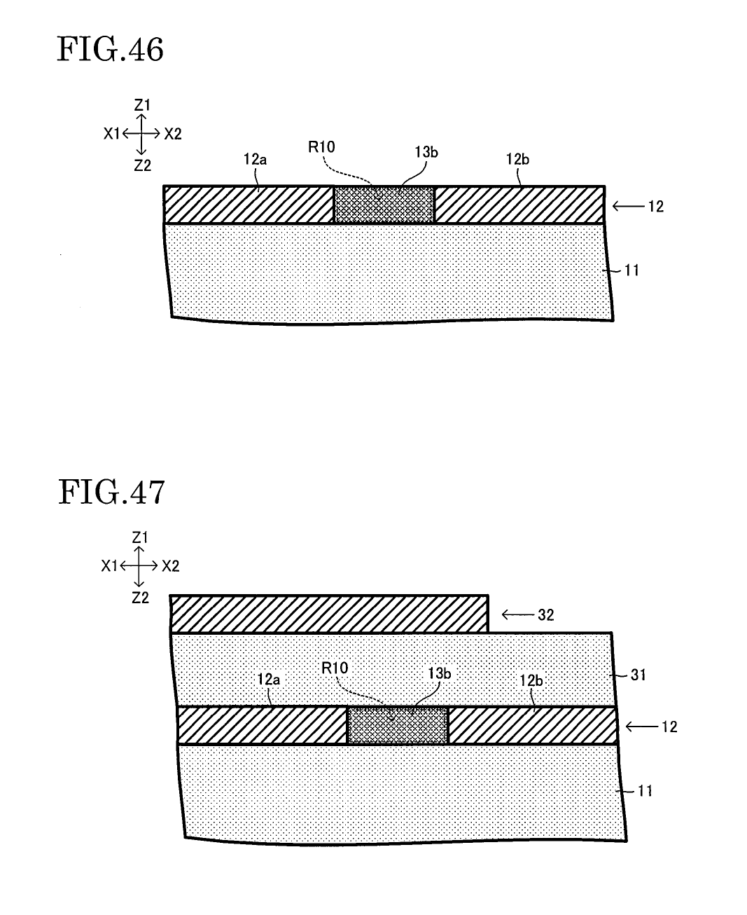

In steps (S11)˜(S14) of FIG. 45, wiring (conductive paste (13b)) is formed in space (R10) between conductive patterns (12a) and (12b) formed on insulation layer 11 the same as in the first embodiment (steps (S11)˜(S14) of FIG. 1) as shown in FIG. 46. Here, space (R10) may be accidentally formed at a portion of disconnected wiring, or may be another space which is formed intentionally. For example, multiple cut portions (spaces (R10)) are formed in advance so that wiring patterns may be changed depending on which one is connected.

In step (S15) of FIG. 45, insulation layer 31 (another insulation layer) is formed on conductive layer 12 (conductive patterns (12a, 12b) and conductive paste (13b)) as shown in FIG. 47, and conductive layer 32 (another conductive layer) is further formed on insulation layer 31. In the present embodiment, conductive patterns (12a, 12b) and conductive paste (13b) are each inner-layer wiring.

Insulation layer 31 is formed by curing thermosetting prepreg (B-stage adhesive sheet), for example. The material of insulation layer 31 is selected freely. RCF (resin-coated copper foil) or ABF (Ajinomoto Build-up Film, made by Ajinomoto Fine-Techno Co., Inc.) or the like may be used instead of prepreg. ABF is film made by sandwiching insulative material with two protective sheets.

Conductive layer 32 is formed by a semi-additive (SAP) method, for example. However, that is not the only option. For example, conductive layer 32 may be formed by any one of the following methods or any combination of two or more of those: panel plating, pattern plating, full additive, SAP, subtractive, transfer and tenting methods.

If required, upper insulation layers and conductive layers may further be formed by repeating the same procedure for forming insulation layer 31 and conductive layer 32 (step (S15) of FIG. 45). In doing so, required numbers of insulation layers and conductive layers may be obtained in a wiring board.

If required, solder resist may further be formed on the outermost conductive layer by screen printing, spray coating, roll coating, lamination or the like, for example.

A wiring board shown in any of FIGS. 2˜10 may be manufactured using the method for manufacturing a wiring board according to the present embodiment.

According to the method for manufacturing a wiring board of the present embodiment, it is easier to reduce the electric resistance of wiring (especially the connected portions) in a wiring board.

FIG. 45 shows an example of manufacturing a wiring board by adding step (S15) of FIG. 45 to the method for forming wiring in a wiring board according to the first embodiment (see FIG. 1). However, that is not the only option. A wiring board may also be manufactured by adding the same step as step (S15) of FIG. 45 to the method for forming wiring in a wiring board according to the second or third embodiment (see FIG. 34 or 40).

Alternatively, using the methods for forming wiring in a wiring board according to the first through third embodiments, a wiring board may also be manufactured in such a way that conductive patterns (12a, 12b) and conductive paste (13b) are each the outermost-layer wiring.

The present invention is not limited to the embodiments above, and may be modified as follows, for example.

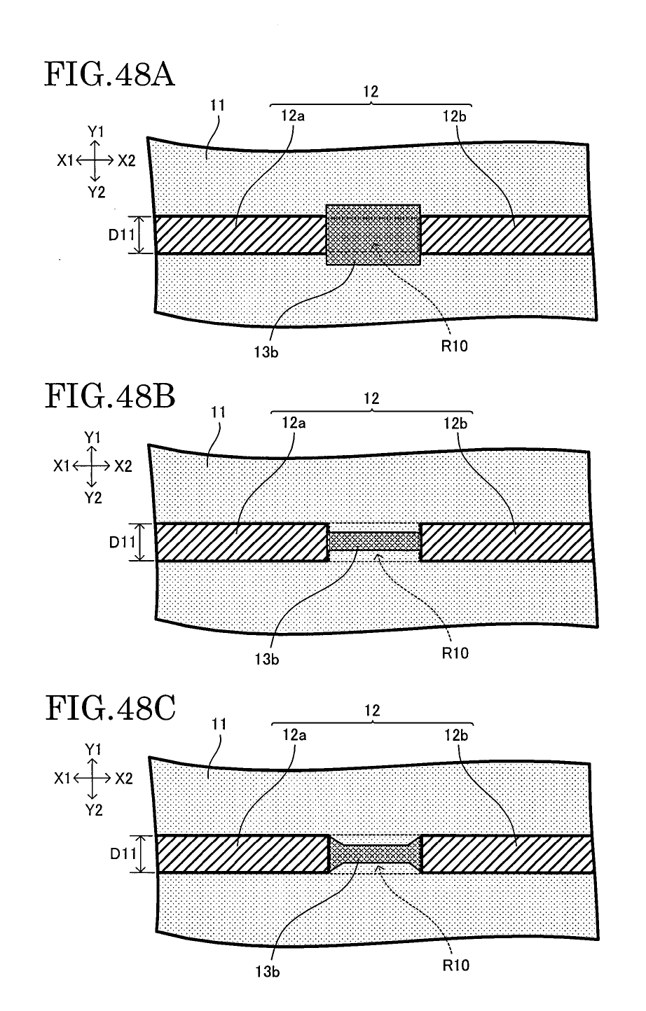

As shown in FIG. 48A, the width of wiring (conductive paste (13b)) formed in space (R10) between conductive patterns (12a) and (12b) may be set greater than width (D11) of conductive pattern (12a) or (12b).

As shown in FIG. 48B, the width of wiring (conductive paste (13b)) formed in space (R10) between conductive patterns (12a) and (12b) may be set smaller than width (D11) of conductive pattern (12a) or (12b).

Alternatively, as shown in FIG. 48C, the width at an end portion of conductive paste (13b) (connected portion of conductive paste (13b) and conductive pattern (12a) or (12b)) where the electric resistance tends to increase may be set greater than the width in the central portion of conductive paste (13b). For example, the width at an end portion of conductive paste (13b) is set the same as width (D11) of conductive pattern (12a) or (12b), and the width in the central portion of conductive paste (13b) is set smaller than width (D11) of conductive pattern (12a) or (12b).

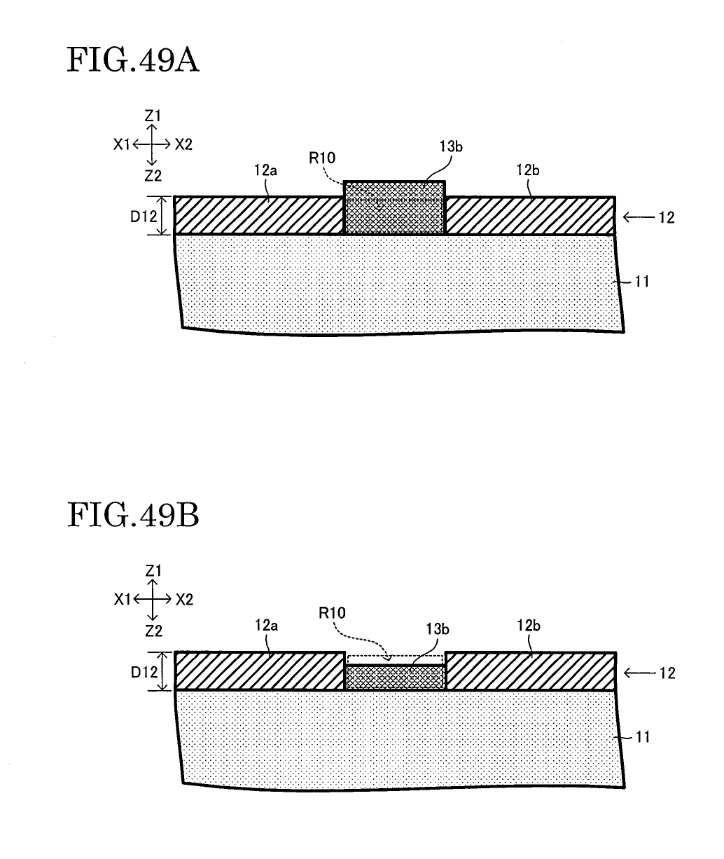

As shown in FIG. 49A, the thickness of wiring (conductive paste (13b)) formed in space (R10) between conductive patterns (12a) and (12b) may be set greater than thickness (D12) of conductive pattern (12a) or (12b). It is easier to form such a structure by using a mask (see FIG. 36B and others, for example).

As shown in FIG. 49B, the thickness of wiring (conductive paste (13b)) formed in space (R10) between conductive patterns (12a) and (12b) may be set smaller than thickness (D12) of conductive pattern (12a) or (12b).

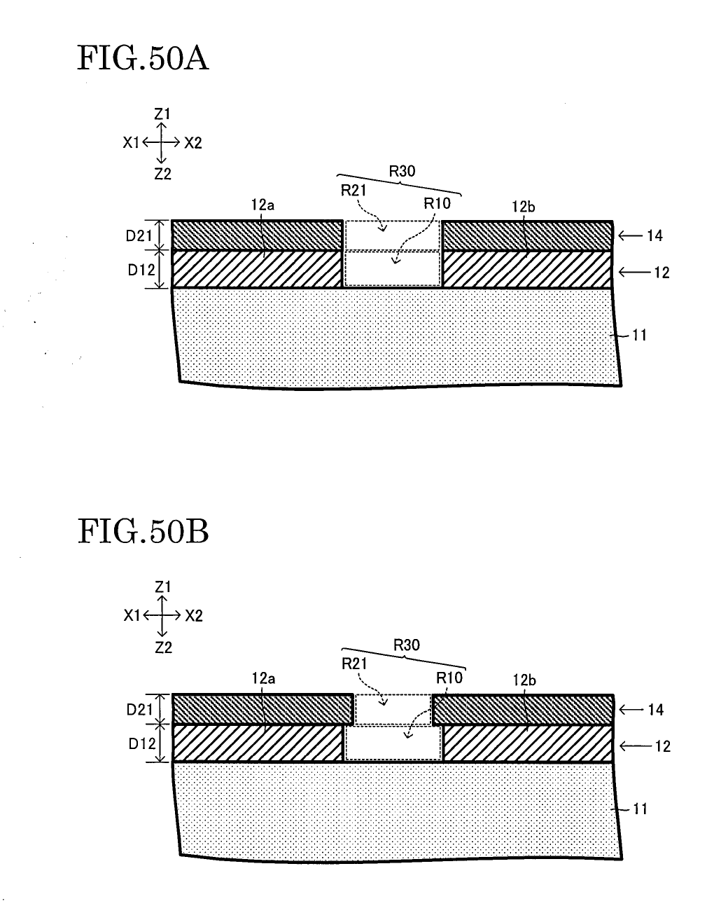

As shown in FIG. 50A, opening portion (R21) of mask 14 positioned to surround space (R10) may have substantially the same opening area as space (R10). The planar shape (X-Y plane) of opening portion (R21) and the planar shape (X-Y plane) of space (R10) may be substantially the same as each other, or may be different from each other.

As shown in FIG. 50B, opening portion (R21) of mask 14 positioned to surround space (R10) may have a smaller opening area than space (R10). According to such a method, making the boundary flat between conductive paste (13b) and conductive pattern (12a) or (12b) is thought to be easier. When conductive paste (13b) and conductive patterns (12a, 12b) form inner-layer wiring, it is especially preferred that the upper surface of conductive paste (13b) and upper surfaces of conductive patterns (12a, 12b) be formed flat so that an upper insulation layer and a conductive layer are laminated on those upper surfaces. The planar shape (X-Y plane) of opening portion (R21) and the planar shape (X-Y plane) of space (R10) may be symmetrical or asymmetrical.

The opening shape of opening portion (R21) of mask 14 may be determined freely. For example, it is preferred to correspond to the shape of wiring to be formed (conductive paste (13b)).

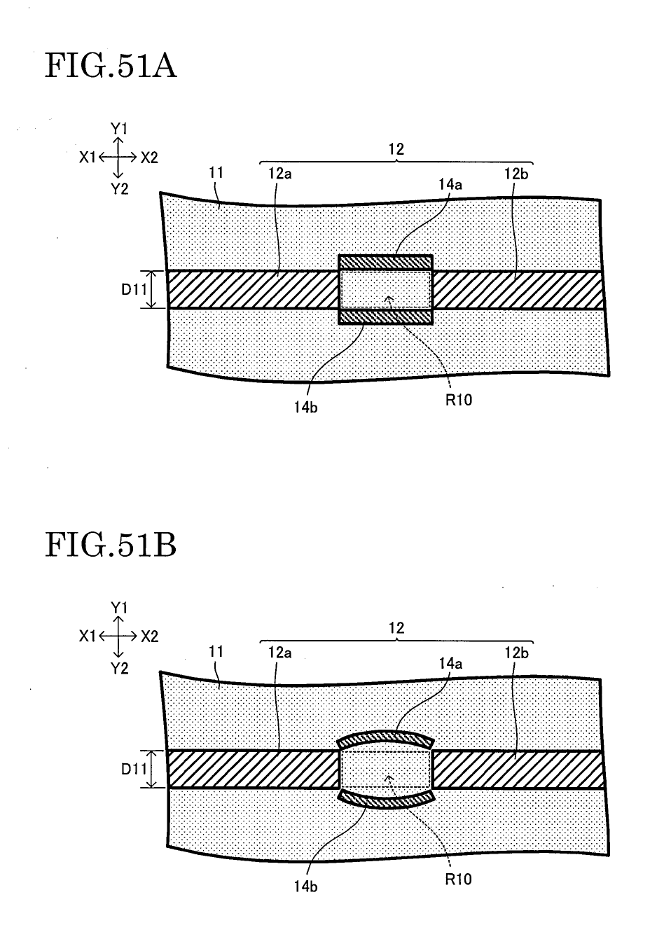

As shown in FIG. 51A or FIG. 51B, prior to forming conductive paste (13a), bar-shaped (linear or arc-shaped) mask (14a) and bar-shaped (linear or arc-shaped) mask (14b) may be positioned on insulation layer 11 in a way to face each other by sandwiching space (R10). Masks (14a) and (14b) are each positioned to be on the same layer (height) as conductive patterns (12a, 12b), for example. In examples shown in FIG. 51A or FIG. 51B, space (R10) is surrounded by masks (14a, 14b) and conductive patterns (12a, 12b). The thicknesses of masks (14a) and (14b) are set substantially the same as the thickness of conductive pattern (12a) or (12b), for example.

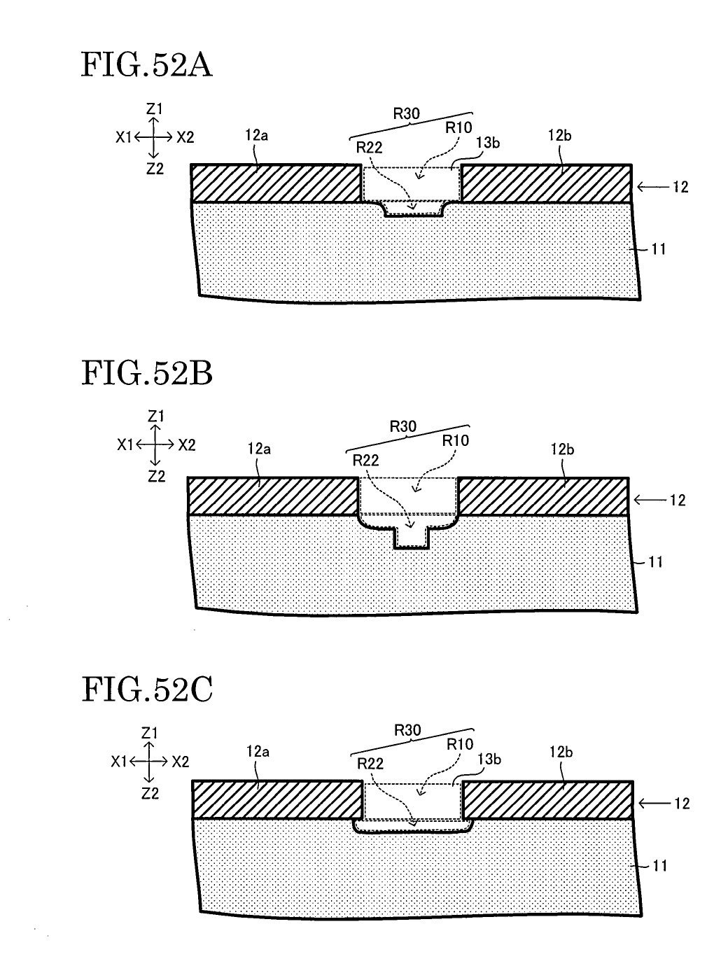

As shown in FIG. 52A, prior to forming conductive paste (13a), it is an option to form recess (R22) having a smaller opening area than space (R10) on the surface of insulation layer 11 in space (R10). Alternatively, the opening area of recess (R22) may vary depending on its depth as shown in FIG. 52B). Yet alternatively, recess (R22) may be formed in a way to expose lower surfaces of conductive patterns (12a, 12b) as shown in FIG. 52C. When such recess (R22) shown in FIG. 52C is formed, it is easier for the wiring (conductive paste (13b)) formed in space (R10) to make contact with both side and lower surfaces of conductive pattern (12a) or (12b). Moreover, when mask 14 shown in FIG. 35B and recess (R22) shown in FIG. 52C are combined, it is easier for the wiring (conductive paste (13b)) formed in space (R10) to make contact with all upper, side and lower surfaces of conductive pattern (12a) or (12b). When the contact area of conductive paste (13b) and conductive pattern (12a) or (12b) increases, it is easier to reduce the resistance at the interface between conductive paste (13b) and conductive pattern (12a) or (12b). Also, it is easier to enhance adhesive strength.

A method for forming wiring in a wiring board, a method for repairing a disconnection in a wiring board and a method for manufacturing a wiring board are not limited to the order and contents shown in each of the above embodiments. Such order and contents may be modified freely within a scope that does not deviate from the gist of the present invention. In addition, some procedure may be omitted depending on usage requirements or the like.

For example, after sintering the wiring (conductive paste (13b)) formed in space (R10) between conductive patterns (12a) and (12b), unsintered conductive paste (13a) may remain without being removed. For example, in the method shown in FIG. 1, step (S14) may be omitted.

Also, when mask 14 is used, mask 14 may remain without being removed after forming conductive paste (13a). For example, in the method shown in FIG. 34, step (S102) may be omitted.

The light source used for sintering may be selected freely. It is preferred to select an appropriate type according to the required wavelength of laser light. For example, the light source may be solid-state lasers, liquid lasers, or gas lasers. In particular, a YAG laser, YVO₄ laser, argon-ion layer, semiconductor laser, fiber laser, disc laser, copper-vapor laser or the like may be used as a light source. A semiconductor laser is small but highly efficient.

The above embodiments and modified examples may be combined freely. It is preferred to select an appropriate combination according to usage requirements or the like. For example, mask 14 (or masks (14a, 14b)) shown in any of FIGS. 50A˜51B may be combined with recess (R22) shown in any of FIGS. 52A˜52C.

In the method for repairing a disconnection in a wiring board described in Japanese Laid-Open Patent Publication 2000-151081, it is thought that electric resistance in wiring tends to increase due to the resin contained in the cured conductive paste. In addition, in the method disclosed in Japanese Laid-Open Patent Publication 2000-151081, a step is required for forming resist in portions except for a portion where wiring is disconnected. Thus, procedures to repair a disconnection are thought to be complex.

According to embodiments of the present invention, wiring is formed to have excellent electrical characteristics. In addition, the electrical characteristics of the repaired portion are excellent after a disconnection is repaired. Also, procedures to repair a disconnection are simplified.

A method for repairing a disconnection in a wiring board according to an embodiment of the present invention includes the following: preparing a substrate having an insulation layer and a conductive pattern formed on the insulation layer; in a disconnected portion of the conductive pattern, forming conductive paste made of conductive particles and non-conductive material; and by irradiating laser light, sintering at least part of the conductive paste formed in the disconnected portion.

A method for manufacturing a wiring board according to another embodiment of the present invention includes forming wiring made of the conductive pattern on the insulation layer using a method for repairing a disconnection in a wiring board according to the present invention.

A method for forming wiring in a wiring board according to yet another embodiment of the present invention includes the following: preparing a substrate having an insulation layer, and a first conductive pattern and a second conductive pattern formed on the insulation layer; in a space between the first conductive pattern and the second conductive pattern, forming conductive paste made of conductive particles and a binder; and by irradiating laser light, sintering at least part of the conductive paste formed in the space.

A wiring board according to still another embodiment of the present invention has an insulation layer; a first conductive pattern and a second conductive pattern formed on the insulation layer; and conductive paste formed in a space between the first conductive pattern and the second conductive pattern. In such a wiring board, at least part of the conductive paste is sintered, and the electric resistance of the sintered conductive paste is in a range of 1.2˜5.0 times the electric resistance of the first conductive pattern and the second conductive pattern respectively.

A wiring board according to still another embodiment of the present invention has an insulation layer; a first conductive pattern and a second conductive pattern formed on the insulation layer; and conductive paste formed in a space between the first conductive pattern and the second conductive pattern. In such a wiring board, at least part of the conductive paste is sintered, and the conductive paste is formed not only in the space but on the first conductive pattern and the second conductive pattern near the space.

Obviously, numerous modifications and variations of the present invention are possible in light of the above teachings. It is therefore to be understood that within the scope of the appended claims, the invention may be practiced otherwise than as specifically described herein.

What is claimed is:

1. A method for repairing a disconnection in a wiring board, comprising:
positioning a substrate comprising an insulation layer and a conductive layer formed on the insulation layer, the conductive layer having a wiring line disconnected such that the wiring line has a disconnected portion formed between a plurality of conductive patterns forming the wiring line;
applying in the disconnected portion between the conductive patterns a conductive paste comprising a non-conductive material and conductive particles such that the conductive paste fills the disconnected portion between the conductive patterns and joins the conductive patterns forming the wiring line in the conductive layer; and
irradiating laser upon the conductive paste applied in the disconnected portion such that at least a portion of the conductive paste in the disconnected portion is sintered and forms a sintered portion connecting the conductive patterns of the wiring line in the conductive layer.

2. The method for repairing a disconnection in a wiring board according to claim 1, wherein the irradiating of the laser comprises selectively scanning the laser on a targeted portion of the conductive paste applied in the disconnected portion such that the targeted portion of the conductive paste applied in the disconnected portion is sintered and forms the sintered portion connecting the conductive patterns of the wiring line in the conductive layer.

3. The method for repairing a disconnection in a wiring board according to claim 1, further comprising drying the conductive paste after the applying of the conductive paste in the disconnected portion but before the irradiating of the laser, wherein the irradiating of the laser comprises irradiating the laser having continuous waves with a wavelength in a range of 300 nm or longer and shorter than 700 nm.

4. The method for repairing a disconnection in a wiring board according to claim 1, wherein the irradiating of the laser comprises irradiating the laser after the applying of the conductive paste without drying the conductive paste, and the laser has continuous waves with a wavelength in a range of 700 nm or longer.

5. The method for repairing a disconnection in a wiring board according to claim 1, wherein the conductive paste has the conductive particles in an amount of 50 wt. % or greater at the irradiating of the laser.

6. The method for repairing a disconnection in a wiring board according to claim 1, wherein the conductive paste has the conductive particles in an amount of 70 wt. % or greater at the irradiating of the laser.

7. The method for repairing a disconnection in a wiring board according to claim 1, wherein the irradiating of the laser comprises irradiating the laser upon the conductive paste such that the conductive paste is sintered to form the sintered portion having a depth of at least 5 μm or greater from a surface of the sintered portion.

8. The method for repairing a disconnection in a wiring board according to claim 1, wherein the irradiating of the laser comprises irradiating the laser upon the conductive paste such that at least the portion of the conductive paste is sintered and forms the sintered portion having an electric resistance in a range of 1.2˜5.0 times an electric resistance of the wiring line.

9. The method for repairing a disconnection in a wiring board according to claim 1, wherein the applying of the conductive paste comprises applying the conductive paste in the disconnected portion such that the conductive paste in the disconnected portion forms a thickness which is greater than thicknesses of the conductive patterns of the wiring line.

10. The method for repairing a disconnection in a wiring board according to claim 1, further comprising removing an unsintered portion of the conductive paste from the substrate after the irradiating of the laser.

11. The method for repairing a disconnection in a wiring board according to claim 1, wherein the applying of the conductive paste comprises applying the conductive paste in the disconnected portion and on end portions of the conductive patterns of the wiring line.

12. The method for repairing a disconnection in a wiring board according to claim 1, wherein the conductive particles of the conductive paste are a metal selected from the group consisting of gold, silver and copper.

13. The method for repairing a disconnection in a wiring board according to claim 1, wherein the applying of the conductive paste and the irradiating of the laser form the sintered portion of the conductive paste has a thickness which is set at 12 μm or greater.

14. A method for manufacturing a wiring board, comprising the method for repairing a disconnection in a wiring board according to claim 1.

15. The method for manufacturing a wiring board according to claim 14, further comprising:
forming a second insulation layer over the insulation layer and the conductive layer; and
forming a second conductive layer on the second insulation layer.

16. A method for forming wiring in a wiring board, comprising:
preparing a substrate comprising an insulation layer and a conductive layer formed on the insulation layer, the conductive layer including a plurality of conductive patterns forming a space between the conductive patterns;
applying in the space between the conductive patterns a conductive paste comprising a non-conductive material and conductive particles such that the conductive paste fills the space between the conductive patterns and joins the conductive patterns in the conductive layer; and
irradiating laser upon the conductive paste applied in the space such that at least a portion of the conductive paste in the space is sintered and forms a sintered portion connecting the conductive patterns forming a wiring line in the conductive layer.

17. The method for forming wiring in a wiring board according to claim 16, wherein the non-conductive material of the conductive paste is a binder.

18. A wiring board, comprising:
an insulation layer;
a conductive layer formed on the insulation layer and including a first conductive pattern and a second conductive pattern; and
a sintered structure formed on the insulation layer and extending in a space between the first conductive pattern and the second conductive pattern such that the sintered structure is connecting the first conductive pattern and the second conductive pattern,
wherein the sintered structure has an electric resistance which is in a range of 1.2˜5.0 times an electric resistance of the first conductive pattern and an electric resistance of the second conductive pattern.

19. The wiring board according to claim 18, wherein the sintered structure extends beyond the space between the first conductive pattern and the second conductive pattern and onto an end portion of the first conductive pattern and an end portion of the of the second conductive pattern adjacent to the space between the first conductive pattern and the second conductive pattern.
